(19) United States
(12) Patent Application Publication
(10) Pub. No.: US 2026/0334001 A1
(43) Pub. Date: Oct. 22, 2026

(54) APPARATUS FOR MANUFACTURING DISPLAY DEVICE AND ELECTRONIC DEVICE MANUFACTURED BY THE APPARATUS

(71) Applicant: Samsung Display Co., LTD., Yongin-si (KR)

(72) Inventors: See Ook LEE, Yongin-si (KR); Eui Jeong KANG, Yongin-si (KR); Su Jeong KIM, Yongin-si (KR); Hye Young KIM, Yongin-si (KR); Eun Jeong JEON, Yongin-si (KR)

(21) Appl. No.: 19/456,293

(22) Filed: Jan. 22, 2026

(30) Foreign Application Priority Data
Apr. 22, 2025 (KR) 10-2025-0052505
Sep. 3, 2025 (KR) 10-2025-0124672

(51) Int. Cl. H10K 59/12; G06F 1/16; H10K 71/40; H10K 71/80

(52) U.S. Cl. CPC H10K 59/1201; G06F 1/1652; H10K 71/40; H10K 71/80

(57) ABSTRACT

Provided are apparatus for manufacturing a display device and an electronic device manufactured by the apparatus. The apparatus includes a first heater which supplies heat to a first bonding area of the display device, and a second heater which supplies heat to a second bonding area of the display device. The display device includes a display panel including a main area including a display area and a sub-area protruding from a side of the main area, an interlayer insulating film attached onto the sub-area, and a package element disposed on the interlayer insulating film. The interlayer insulating film includes a package area and a general area, the package element is disposed on the package area, the first bonding area is an area in which the package area and the sub-area overlap, and the second bonding area may be an area in which the general area and the sub-area overlap.

This application claims priority to Korean Patent Application No. 10-2025-0052505, filed on April 22, 2025, and Korean Patent Application No. 10-2025-0124672, filed on September 3, 2025, and all the benefits accruing therefrom under 35 U.S.C. §119, the contents of which in their entirety are herein incorporated by reference.

### BACKGROUND

### FIELD

The present disclosure relates to an apparatus for manufacturing a display device and an electronic device manufactured by the apparatus.

### DESCRIPTION OF THE RELATED ART

An electroluminescent display may be classified as an inorganic light-emitting display device or an organic light-emitting display device based on a material of a light-emitting layer included in the electroluminescent display. An active matrix type organic light-emitting display device includes an organic light-emitting diode (hereinafter, referred to as "OLED") that emits light by itself, and an active matrix type organic light-emitting display device has an advantage in that a response speed is fast and luminous efficiency and luminance are high and a viewing angle is wide. In the organic light-emitting display device, the OLED (organic light-emitting diode) is formed in each of pixels. The organic light-emitting display device has a fast response speed, excellent luminous efficiency, luminance, and a large viewing angle. Further, the organic light-emitting display device can express a black gray scale as pure black and thus has excellent contrast ratio and color reproduction rate.

### SUMMARY

A purpose of the present disclosure is to improve operational reliability of a display device.

The technical purposes of the present disclosure are not limited to the above-mentioned

technical purposes, and other technical purposes not mentioned may be clearly understood by a person skilled in the art of the present disclosure from the following description.

Specific details of other embodiments are included in the detailed description and drawings.

According to various embodiments of the disclosure, an apparatus for manufacturing a display device includes a first heater which supplies heat to a first bonding area of the display device, and a second heater which supplies heat to a second bonding area of the display device, and the display device includes a display panel including a main area including a display area and a sub-area protruding from a side of the main area, an interlayer insulating film attached onto the sub-area, and a package element disposed on the interlayer insulating film, wherein the interlayer insulating film includes a package area and a general area arranged in a first direction from the package area, the package element is disposed on the package area, the first bonding area is an area in which the package area and the sub-area overlap each other in a thickness direction of the display panel, and the second bonding area may be an area in which the general area and the sub-area overlap each other in the thickness direction of the display panel.

According to various embodiments of the disclosure, the apparatus may further include a thermal bonding device which supplies heat to the first bonding area and the second bonding area.

According to various embodiments of the disclosure, when the heat is supplied from the thermal bonding device to the display device, the interlayer insulating film may be disposed between the first heater and the thermal bonding device.

According to various embodiments of the disclosure, when the heat is supplied from the thermal bonding device to the display device, the interlayer insulating film may be disposed between the second heater and the thermal bonding device.

According to various embodiments of the disclosure, the apparatus may further include a support plate which transfers heat supplied to the support plate from the first heater and heat supplied to the support plate from the second heater to the display device and supports the display device.

According to various embodiments of the disclosure, when the heat from the first heater is supplied to the display device, the support plate may be disposed between the first heater and the display panel.

According to various embodiments of the disclosure, when the heat from the second heater is supplied to the display device, the support plate may be disposed between the second heater and the display panel.

According to various embodiments of the disclosure, when the heat from the first heater and the heat from the second heater are supplied to the display device, an amount of the heat supplied from the first heater to the first bonding area may be different from an amount of the heat supplied from the second heater to the second bonding area.

According to various embodiments of the disclosure, when the heat from the first heater and the heat from the second heater are supplied to the display device, an amount of heat supplied from the first heater to the first bonding area may be greater than an amount of heat supplied from the second heater to the second bonding area.

According to various embodiments of the disclosure, the first bonding area has a first width in the first direction, the second bonding area has a second width in the first direction, and the first width may be smaller than the second width.

According to various embodiments of the disclosure, the support plate may include a first support plate supporting a portion of the display panel overlapping the first bonding area, and a second support plate supporting a portion of the display panel overlapping the second bonding area, wherein a surface area per unit volume of the first support plate may be smaller than a surface area per unit volume of the second support plate.

According to various embodiments of the disclosure, the second support plate may include a recess defined in the thickness direction.

According to various embodiments of the disclosure, the display device may further include an anisotropic conductive film disposed between the display panel and the interlayer insulating film, the first heater may supply heat to an area in which the anisotropic conductive film and the first bonding area overlap each other in the thickness direction, and the second

heater may supply heat to an area in which the anisotropic conductive film and the second bonding area overlap each other in the thickness direction.

According to various embodiments of the disclosure, the apparatus may further include a thermal bonding device which supplies heat to the first bonding area and the second bonding area, and when heat is supplied to the display device, a temperature of the thermal bonding device may be greater than a temperature of the support plate.

According to various embodiments of the disclosure, when the heat is supplied from the thermal bonding device to the display device, a surface heat loss rate of the package area may be greater than a surface heat loss rate of the general area.

According to various embodiments of the disclosure, an electronic device includes a processor which provides an image signal, a display module which receives the image signal from the processor and displays an image, and a power module which supplies power to the display module, wherein the display module includes a display panel including a main area including a display area and a sub-area protruding from a side of the main area, an interlayer insulating film attached onto the sub-area by an apparatus for manufacturing a display device, and a package element disposed on the interlayer insulating film, and the apparatus for manufacturing the display device includes a first heater which supplies heat to a first bonding area of the display module, and a second heater which supplies heat to a second bonding area of the display module, wherein the interlayer insulating film includes a package area and a general area arranged in a first direction from the package area, the package element is disposed on the package area, the first bonding area is an area in which the package area and the sub-area overlap each other in a thickness direction of the display panel, and the second bonding area may be an area in which the general area and the sub-area overlap each other in the thickness direction of the display panel.

According to various embodiments of the disclosure, the apparatus for manufacturing the display device may further include a thermal bonding device which supplies heat to the first bonding area and the second bonding area.

According to various embodiments of the disclosure, the apparatus for manufacturing the display device may further include a support plate which transfers heat supplied to the

support plate from the first heater and heat supplied to the support plate from the second heater to the display module and supports the display module.

According to various embodiments of the disclosure, when the heat from the first heater and the heat from the second heater are supplied to the display module, an amount of heat supplied from the first heater to the first bonding area may be different from an amount of heat supplied from the second heater to the second bonding area.

According to various embodiments of the disclosure, when the heat from the first heater and the heat from the second heater are supplied to the display module, a surface heat loss rate of the package area may be greater than a surface heat loss rate of the general area.

According to various embodiments disclosed herein, curing of the first adhesive member between the display panel and the interlayer insulating film may be uniform across the first bonding area and the second bonding area. Accordingly, compression quality of the bonding area may be improved, and the operational reliability of the display device may be improved.

### BRIEF DESCRIPTION OF DRAWINGS

The above and other aspects and features of the present disclosure will become more apparent by illustrating in detail embodiments thereof with reference to the attached drawings, in which:

FIG. 1 is a perspective view illustrating an electronic device according to an embodiment of the present disclosure;

FIG. 2 is an exploded perspective view illustrating the electronic device of FIG. 1 according to an embodiment of the present disclosure;

FIG. 3 is a plan view illustrating a display device according to an embodiment of the present disclosure;

FIG. 4 is a cross-sectional view illustrating a portion taken along a line X1-X1' of FIG. 3;

FIG. 5 is a block diagram illustrating a display device according to an embodiment of the present disclosure;

FIG. 6 is a plan view illustrating a state in which a display device according to an embodiment of the present disclosure is not bent;

FIG. 7 is a plan view illustrating a state in which a display device according to an embodiment of the present disclosure is bent;

FIG. 8 is a plan view illustrating a state in which a conventional display device is bent;

FIG. 9 is a partially enlarged view illustrating an area J of FIG. 7;

FIG. 10 is a cross-sectional view illustrating a portion taken along a line Y1-Y1' of FIG. 7;

FIG. 11 is a cross-sectional view illustrating a portion taken along a line Y2-Y2' of FIG. 7;

FIG. 12 is a partially enlarged view illustrating an area K of FIG. 11;

FIG. 13 is a perspective view schematically illustrating a process of manufacturing a display device according to an embodiment of the present disclosure;

FIG. 14 is a cross-sectional view illustrating a portion taken along a line Z1-Z1' of FIG. 6;

FIG. 15 is a cross-sectional view illustrating a portion taken along a line Z2-Z2' of FIG. 13;

FIG. 16 is a graph illustrating a temperature of each of a first bonding area and a second bonding area over time;

FIG. 17 is a cross-sectional view illustrating a manufacturing process of a display device according to an embodiment of the present disclosure;

FIG. 18 is a graph illustrating a temperature of each of a first bonding area and a second bonding area over time when a display device is manufactured as illustrated in FIG. 17;

FIG. 19 is a cross-sectional view illustrating an apparatus for manufacturing a display device according to a first embodiment of the present disclosure;

FIG. 20 is a graph illustrating a temperature of each of a first bonding area and a second bonding area over time when a display device is manufactured as illustrated in FIG. 19;

FIG. 21 is a cross-sectional view illustrating an apparatus for manufacturing a display device according to a second embodiment of the present disclosure;

FIG. 22 is a modified example of FIG. 21;

FIG. 23 is a cross-sectional view illustrating an apparatus for manufacturing a display device according to a third embodiment of the present disclosure;

FIG. 24 is a perspective view illustrating an apparatus for manufacturing a display device according to a fourth embodiment of the present disclosure;

FIG. 25 is a block diagram of an electronic device according to an embodiment of the present disclosure; and

FIG. 26 is a schematic diagram of an electronic device according to various embodiments of the present disclosure.

### DETAILED DESCRIPTION

The advantages and features of the embodiments disclosed herein, and methods of achieving them, will become apparent upon reference to the embodiments described in detail with accompanying drawings. However, the invention according to the present disclosure is not limited to the embodiments disclosed herein, but will be embodied in many different forms, and the example embodiments are provided to make the disclosure complete and to fully inform one of ordinary skill in the art to which the invention according to the present disclosure belongs, and the invention according to the present disclosure is defined by the scope of the claims.

References to an element or layer as being “on” another element or layer include both cases in which another layer or element is directly on top of or interposed between other elements. Throughout this specification, like reference numerals refer to like components. The shapes, sizes, proportions, angles, numbers, etc. disclosed in the drawings to illustrate embodiments are examples and are not intended to be limiting to those illustrated herein.

Although first, second, and the like are used to describe various components, the components are not limited by these terms. Thus, a first component referred to herein may also be a second component within the technical idea of the present invention.

The terminology used herein is for the purpose of describing particular embodiments and is not intended to be limiting. As used herein, “a,” “an,” “the,” and “at least one” do not denote a limitation of quantity, and are intended to include both the singular and plural, unless the context clearly indicates otherwise. For example, “an element” has the same meaning as “at least one element," unless the context clearly indicates otherwise. “At least one” is not to be construed as limiting “a” or “an.” “Or” means “and/or.” As used herein, the term “and/or”

includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, comp

The term “substantially,” as used herein, means approximately or actually. The term “substantially equal” means approximately or actually equal. The term “substantially the same” means approximately or actually the same. The term “substantially identical” means approximately or actually identical. The term “substantially perpendicular” means approximately or actually perpendicular.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Embodiments are described herein with reference to cross section illustrations that are schematic illustrations of example embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as "A or B”, "at least one of A and B”, "at least one of A or B”, "A, B, or C”, "at least one of A, B, and C”, and "at least one of A, B, or C”, may include any one of, or all possible combinations of the items enumerated together in a corresponding one of the phrases.

Each of the features of the various embodiments disclosed herein may be combined or combinable with each other, in part or in whole, and may be technically interlocked and operated in a variety of ways, and each embodiment may be practiced independently of or in conjunction with one another.

Specific embodiments will be described herein with reference to the accompanying drawings. Configurations that function substantially the same between embodiments are given the same drawing designation and repeated description is omitted.

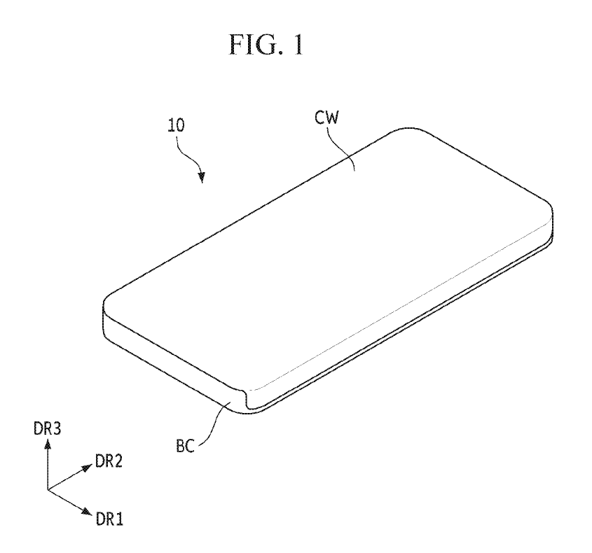

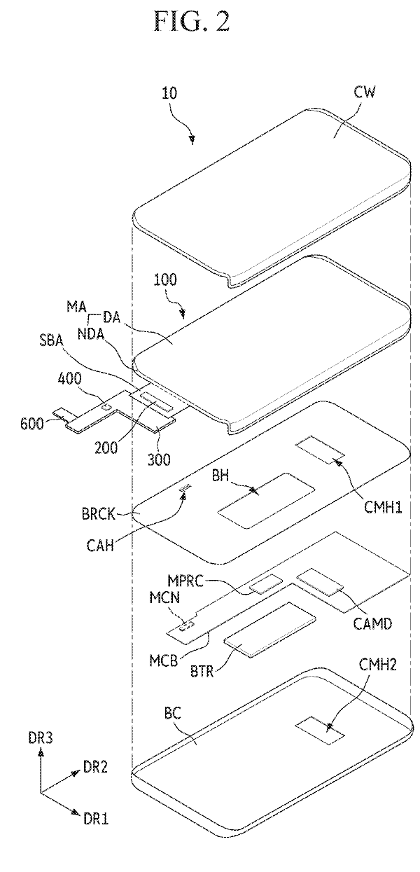

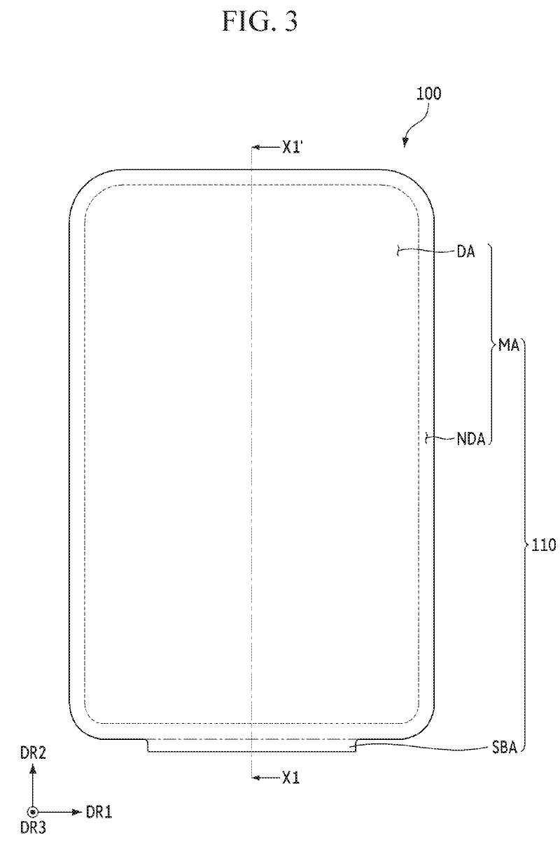

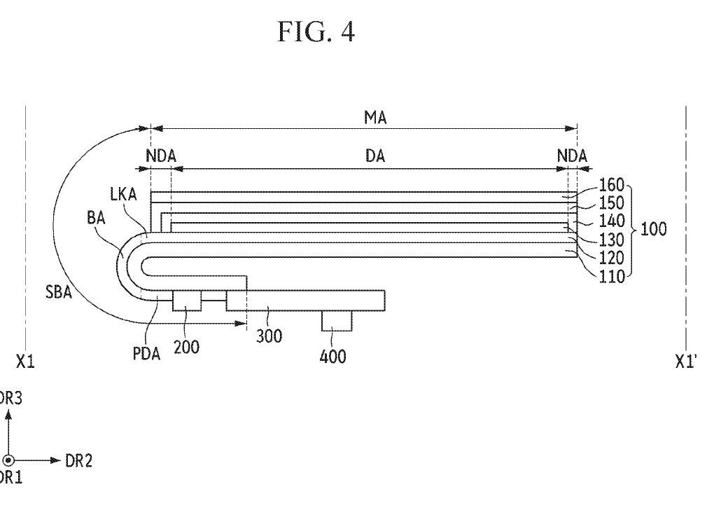

FIG. 1 is a perspective view illustrating an electronic device according to an embodiment of the present disclosure. FIG. 2 is an exploded perspective view illustrating the electronic device of FIG. 1 according to an embodiment of the present disclosure. FIG. 3 is a plan view illustrating a display device according to an embodiment of the present disclosure. FIG. 4 is a cross-sectional view illustrating a portion taken along a line X1-X1' of FIG. 3.

Referring to FIGS. 1 to 4, an electronic device 10 according to an embodiment is a device having a function of displaying an image on a display area. The electronic device 10 may provide portability. In an example, the electronic device 10 may be a portable electronic device such as a mobile phone, a smart phone, a tablet personal computer (PC), a smart watch, a watch phone, a mobile communication terminal, an electronic handbook, an electronic book, a portable multimedia player (PMP), a navigation system, an ultra mobile PC (UMPC), and the like. However, the electronic device 10 according to an embodiment is not limited to the portable electronic device, and may be a large-sized device such as a television, a laptop computer, a monitor, a billboard, and the internet of things (IOT).

The electronic device 10 according to an embodiment may include a cover window CW and a lower cover BC acting as a housing for protecting the display device 100.

The electronic device 10 may further include a display device 100, a bracket BRCK, and a main circuit board MCB which are received in a space defined between the cover window CW and the lower cover BC.

The display device 100 may include a main area MA including a display area DA in which an image is displayed and a non-display area NDA around the display area DA, and a sub-area SBA protruding from a side of the main area MA.

The display device 100 may further include a display driving circuit 200 disposed in the sub-area SBA, a display circuit board 300 bonded to a side of the sub-area SBA, a touch driving circuit 400 mounted on the display circuit board 300, and a cable 600 extending from a side of the display circuit board 300.

In the present disclosure, a first direction DR1 may be a direction parallel to a short side of the electronic device 10 in a plan view, that is, a transverse direction of the electronic device 10. A second direction DR2 may be a direction parallel to a long side of the electronic device 10 in a plan view, that is, a longitudinal direction of the electronic device 10. A third direction DR3 may be a thickness direction of the electronic device 10.

The electronic device 10 may have a shape approximate to a rectangle in a plan view. For example, the electronic device 10 may have a rectangular shape in a plan view having a short side extending in the first direction DR1 and a long side extending in the second direction DR2. A corner at which the short side extending in the first direction DR1 and the long side extending in the second direction DR2 meet each other may be rounded to have a predetermined curvature or may be formed at a right angle. The shape in a plan view of the electronic device 10 is not limited to the rectangular shape, and may be formed in another polygonal shape, a circular shape, or an oval shape.

The cover window CW may be disposed on top of the display device 100 and cover an upper surface of the display device 100. The cover window CW may serve to protect the upper surface of the display device 100.

The display device 100 may be disposed under the cover window CW. The display device 100 may include an upper surface portion facing an upper surface portion of the cover window CW, a left surface portion facing a left surface portion of the cover window CW, and a right surface portion facing a right surface portion of the cover window CW. The left side surface portion of the display device 100 may extend from a left side of the upper surface portion of the display device 100 , and the right side surface portion of the display device 100 may extend from a right side of the upper surface portion of the display device 100.

The display device 100 may include the main area MA serving as a display surface and the sub-area SBA protruding from at least a portion of a side of the main area MA.

The main area MA may include the display area DA for displaying an image and the non-display area NDA around the display area DA. The non-display area NDA may be disposed outside the display area DA. The non-display area NDA may be an edge area of the main area MA.

The sub-area SBA may protrude from a side of the main area MA in the second direction DR2. A length of the sub-area SBA in the first direction DR1 may be smaller than or equal to a length of the main area MA in the first direction DR1. A length of the sub-area SBA in the second direction DR2 may be smaller than a length of the main area MA in the second direction DR2. However, embodiments of the present disclosure are not limited thereto.

As a portion of the sub-area SBA is deformed to a bent shape, another portion of the sub-area SBA may overlap the main area MA in the third direction DR3 (or thickness direction).

The display driving circuit 200 may be mounted in the sub-area SBA, and the display circuit board 300 may be attached thereto.

An end of the display circuit board 300 may be attached onto the pads disposed at a lower edge of the sub-area SBA of the display device 100 using an anisotropic conductive film. The anisotropic conductive film ACF may be formed such that the anisotropic conductive film ACF extends in the first direction DR1.

The display circuit board 300 may be a flexible printed circuit board (FPCB) that may be bent, a rigid printed circuit board (PCB) that maintains a flat shape, or a composite printed circuit board including both a rigid printed circuit board and a flexible printed circuit board.

The display driving circuit 200 may output data signals of data lines of a circuit layer disposed in the display area DA based on control signals, powers, and voltages supplied via the display circuit board 300. The data signals may be transmitted to light-emitting pixel drivers via the data lines.

The display driving circuit 200 may be provided as an integrated circuit (IC), and may be mounted in the sub-area SBA of the display device 100 in a chip on glass (COG) manner, a chip on plastic (COP) manner, or an ultrasonic manner. However, this is an example, and embodiments of the present disclosure are not limited thereto. For example, the display driving circuit 200 may be mounted on the display circuit board 300.

According to an embodiment, the touch driving circuit 400 may be further mounted in the sub-area SBA of the display device 100. The touch driving circuit 400 may be mounted on the display circuit board 300. The touch driving circuit 400 may be electrically connected to a touch sensor layer of the display device 100.

The bracket BRCK may be disposed under the display device 100. The bracket BRCK may include plastic or metal. The bracket BRCK may include a first camera hole CMH 1 into which a camera device CAMD is inserted, a battery hole BH in which a battery BTR is disposed, and a cable hole CAH through which the cable 600 connected to the display circuit board 300 passes. The main circuit board MCB and the battery BTR may be disposed under the bracket BRCK.

The main circuit board MCB may be a printed circuit board or a flexible printed circuit board. The main circuit board MCB may include a main processor MPRC, the camera device CAMD, and a main connector MCN. The main processor MPRC may be embodied as an integrated circuit. The main processor MPRC may control all functions of the electronic device 10. For example, the main processor MPRC may output digital video data to the display driving circuit 200 via the display circuit board 300 such that the display device 100 displays an image. In some aspects, the main processor MPRC may receive touch data including touch coordinates of touch of the user from the touch driving circuit 400, determine whether the user touches the display device or approaches the display device, and then execute an operation corresponding to the touch input or the proximity input from the user. For example, the main processor MPRC may execute an application indicated by an icon touched by the user or perform an operation corresponding thereto. The main processor MPRC may be an application processor embodied as an integrated circuit, a central processing unit, or a system chip. In some aspects, a mobile communication module capable of transmitting and receiving a wireless signal to and from at least one of a base station, an external terminal, and a server on a mobile communication network may be further mounted on the main circuit board MCB. The wireless signal may include various types of data according to transmission and reception of a voice signal, a video call signal, or a text/multimedia message.

The camera device CAMD may be disposed on each of an upper surface and a lower surface of the main circuit board MCB, the main processor MPRC may be disposed on the upper surface of the main circuit board MCB, and the main connector MCN may be disposed on the lower surface of the main circuit board MCB. The camera device CAMD processes an image frame such as a still image or a video obtained by an image sensor in a camera mode and outputs the processed image frame to the main processor MPRC.

The cable 600 passing through the cable hole CAH of the bracket BRCK may be connected to the main connector MCN. Accordingly, the main circuit board MCB may be electrically connected to the display circuit board 300.

The battery BTR may be disposed not to overlap the main circuit board MCB in the third direction DR3 (or thickness direction). The battery BTR may overlap the battery hole BH of the bracket BRCK in the third direction DR3 (or the thickness direction).

The lower cover BC may be disposed under the main circuit board MCB and the battery BTR. The lower cover BC may be fastened and fixed to the bracket BRCK. The lower cover BC may constitute an upper surface, a lower surface, and a lower surface of the electronic device 10. The lower cover BC may include plastic, metal, or both plastic and metal. The lower cover BC may include a second camera hole CMH 2 through which a lower surface of the camera device CAMD is exposed. The position of the camera device CAMD and the positions of the first camera hole CMH1 and the second camera hole CMH2 corresponding to the camera device CAMD are not limited as illustrated.

The display device 100 may be a light-emitting display device such as an organic light-emitting display device using an organic light-emitting diode, a quantum dot light-emitting display device including a quantum dot light-emitting layer, an inorganic light-emitting display device including an inorganic semiconductor, and a micro light-emitting display device using a micro or nano light-emitting diode (micro LED or nano LED). Hereinafter, a description will be made mainly based on an example in which the display device 100 is the organic light-emitting display device. However, embodiments of the present disclosure are not limited thereto, and may be applied to the display device including an organic insulating material, an organic light-emitting material, or a metal material.

The display device 100 may be formed to be flat. However, embodiments of the present disclosure are not limited thereto. For example, the display device 100 may include a curved portion formed at each of left and right ends and having a constant curvature or a varying curvature. In some aspects, the display device 100 may be flexibly formed to be bent, folded, or rolled.

The sub-area SBA may include a bendable area BA that is deformed into a bent shape, a link area LKA disposed between a side of the bendable area BA and the main area MA, and a pad area PDA connected to the other side of the bendable area BA. In an example in which the bendable area BA is deformed into a bent shape, the pad area PDA may be disposed on a rear surface of the display device 100 and may overlap the main area MA in the third direction DR3 (or thickness direction).

According to an embodiment, the display device 100 may include a substrate 110, a circuit layer 120 disposed on the substrate 110, an element layer 130 disposed on the circuit layer 120, and a sealing layer 140 disposed on the element layer 130. The display device 100 may further include a touch sensor layer 150 disposed on the sealing layer 140. The display device 100 may further include a polarizing layer 160 disposed on the touch sensor layer 150 to reduce reflection of external light.

The display area DA may include light-emitting areas from which light beams are emitted, respectively, and a non-light-emitting area disposed between adjacent ones of the light-emitting areas.

The sub-area SBA may include the bendable area BA that is deformed into a bent shape, the link area LKA disposed between a side of the bendable area BA and the main area MA, and the pad area PDA connected to the other side of the bendable area BA.

The circuit layer 120 may include light-emitting pixel drivers electrically connected to the light-emitting elements, and data lines for transmitting data signals to the light-emitting pixel drivers. The element layer 130 may include the light-emitting elements respectively disposed in the light-emitting areas. The sealing layer 140 may cover the element layer 130. The sealing layer 140 may include a stack structure including two or more inorganic layers and at least one organic layer disposed therebetween. The touch sensor layer 150 may be disposed on the sealing layer 140 and may correspond to the main area MA. The touch sensor layer 150 may include touch electrodes for sensing a touch of a person or an object. The polarizing layer 160 blocks external light reflected from the touch sensor layer 150, the sealing layer 140, the element layer 130, the circuit layer 120, and interfaces therebetween, thereby preventing a decrease in visibility of an image due to reflection of the external light.

The display driving circuit 200 may be mounted in the pad area PDA of the sub-area SBA of the substrate 110.

The display circuit board 300 may contact and be connected to the pads disposed in the pad area PDA of the sub-area SBA of the substrate 110. In an example in which the bendable area BA is deformed into a bent shape, the display driving circuit 200 and the display circuit board 300 may be disposed under the substrate 110.

The display driving circuit 200 may be electrically connected to the data lines via data supply lines. The display driving circuit 200 may output the data signals of the light-emitting pixel drivers to the data lines, based on control signals and power voltages supplied from the display circuit board 300. An end of the display circuit board 300 may be attached and contact and be connected to the pads using an anisotropic conductive film.

The touch driving circuit 400 may be mounted on the display circuit board 300. The touch driving circuit 400 may be electrically connected to the touch sensor layer 150 of the display device 100. The touch driving circuit 400 may apply a touch driving signal to driving lines of the touch sensor layer 150 and receive a touch sensing signal from sensing lines. In some aspects, the touch driving circuit 400 may sense charge variations of the capacitances based on the touch sensing signal and determine whether the user touches the display device and whether the user is close thereto based on the sensing result.

The display circuit board 300 may be attached and contact and be connected to the pads. The pads may include data pads electrically connected to the display driving circuit 200 and constant voltage transmission pads for transmitting a constant voltage.

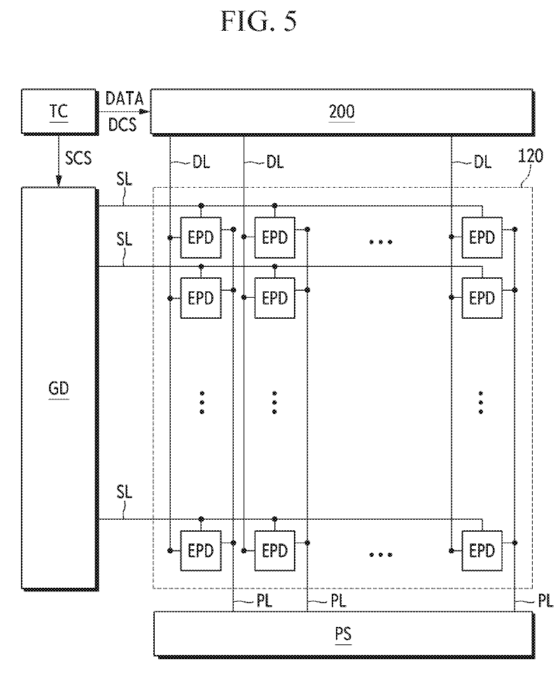

FIG. 5 is a block diagram illustrating a display device according to an embodiment of the present disclosure.

Referring to FIG. 5, the circuit layer 120 of the display device according to an embodiment may include the light-emitting pixel drivers EPD electrically connected to the light-emitting elements of the element layer, and the data lines DL transmitting the data signals to the light-emitting pixel drivers EPD.

The circuit layer 120 may further include one or more scan lines that transmit one or more scan signals to the light-emitting pixel drivers EPD.

According to an embodiment, the display device may further include the display driving circuit 200 that outputs the data signals corresponding to the luminance levels of the light-emitting elements to the data lines DL.

According to an embodiment, the display device may further include a gate driver GD that outputs scan signals to the scan lines SL, a power supply PS that supplies power and voltages to the light-emitting pixel drivers EPD, and a timing controller TC that controls an operation timing of each of the display driving circuit 200 and the gate driver GD.

The timing controller TC receives an image signal supplied from an external source to the display device. The timing controller TC may output image data DATA and a data control signal DCS to the display driving circuit 200. The timing controller TC may generate a scan control signal SCS for controlling an operation timing of the gate driver GD.

The display driving circuit 200 may convert the image data DATA into analog data voltages and output the analog data voltages to the data lines DL.

The gate driver GD may generate the scan signals according to the scan control signal SCS and sequentially output the scan signals to the scan lines SL. The scan signal may have a pulse having a level changing to a first gate level voltage VGL1 or a second gate level voltage VGL2.

The power supply PS may supply various powers and voltages supportive of driving the light-emitting pixel drivers EPD. In one example, the power supply PS may supply constant voltages such as a first power and a second power for generating a driving signal of the light-emitting elements, a gate initialization voltage and a bias voltage for initializing the light-emitting pixel drivers EPD, and an anode initialization voltage for initializing the light-emitting elements.

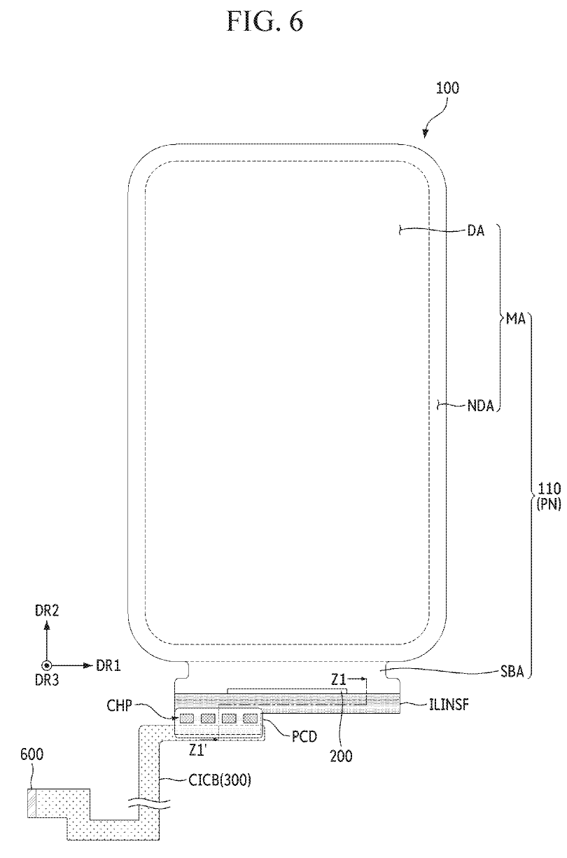

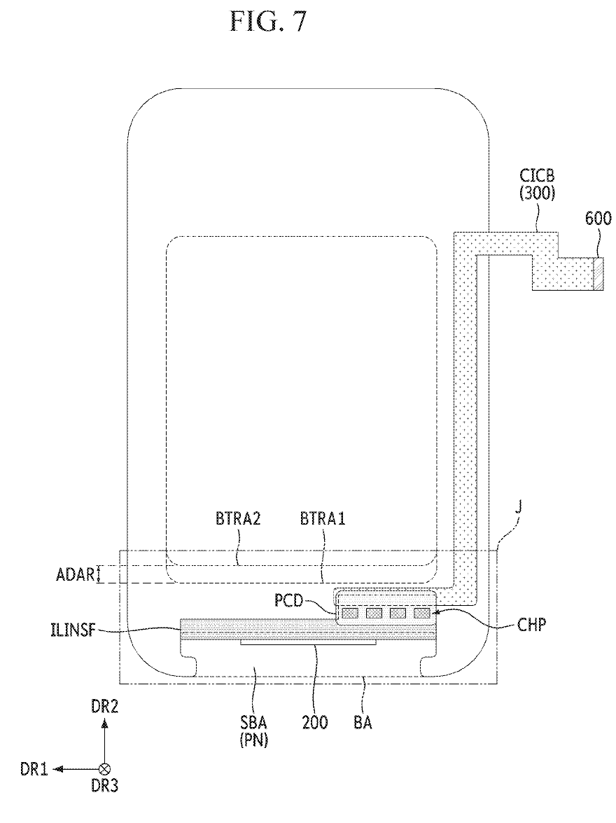

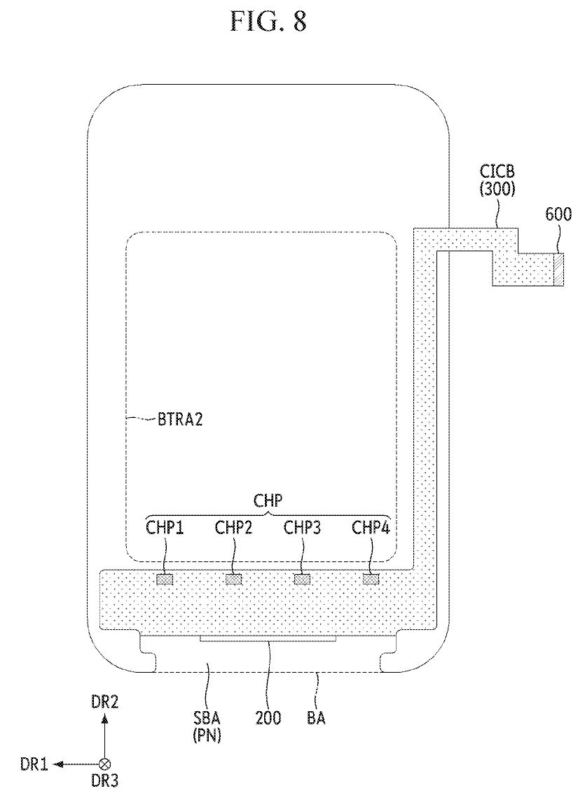

FIG. 6 is a plan view illustrating a state in which a display device according to an embodiment of the present disclosure is not bent. FIG. 7 is a plan view illustrating a state in which a display device according to an embodiment of the present disclosure is bent. FIG. 8 is a plan view illustrating a state in which a conventional display device is bent.

Referring to FIGS. 6 to 8, the display device according to an embodiment of the present disclosure may include a display panel PN, the display driving circuit 200, an interlayer insulating film ILINSF, a package element PCD, a circuit board CICB (or a display circuit board 300), and a cable 600. The display panel PN may include the main area MA and the sub-area SBA. The main area MA may include the display area DA and the non-display area NDA.

The display panel PN may be electrically connected to the package element PCD and the circuit board CICB (or the display circuit board 300) via the interlayer insulating film ILINSF having wiring layers disposed therein. The interlayer insulating film ILINSF may be attached to the sub-area SBA of the display panel PN via a bonding area. The interlayer insulating film ILINSF may be electrically connected to the package element PCD and the circuit board CICB (or the display circuit board 300).

The package element PCD may include a plurality of chips CHP. The package element PCD may be implemented by integrating several semiconductor chips CHP into one package. In the package element PCD, a complex system including the plurality of chips CHP may be implemented into one small package.

For example, the package element PCD may include the plurality of chips CHP mounted on a conventional circuit board CICB (or the display circuit board 300). The plurality of chips CHP may include, for example, a first chip CHP1, a second chip CHP2, a third chip CHP3, and a fourth chip CHP4. However, the number of chips CHP is not limited thereto. For example, the first chip CHP 1 may be a touch driving circuit. The second chip CHP2 may be an ADC (Analog-to-Digital Converter). The third chip CHP3 may be a Microcontroller Unit (MCU). The fourth chip CHP4 may be a memory chip CHP (e.g., a flash memory) or a Power Management Integrated Circuit (PMIC). In addition to the above-described example, the plurality of chips CHP may further include an interface chip CHP, a security chip CHP, a sensor correction and calibration integrated circuit, or the like, and the example of the chip CHP is not limited thereto.

The implementation of integrating several semiconductor chips CHP into one package as in the package element PCD may be referred to as an System in Package (SiP). In an example in which the SiP (system in package) such as the package element PCD is implemented, several functions are integrated into one small package, such that a space may be saved or signal interference may be reduced, and in some cases, optimized power management may be achieved.

In a conventional display device, a space of a circuit board CICB (or a display circuit board 300) is relatively large, and a plurality of chips CHP are disposed in a distributed manner in a relatively large space of the circuit board CICB (or the display circuit board 300). These chips CHP may be connected to the display panel PN via an external line of the circuit board CICB. The conventional circuit board CICB (or the display circuit board 300) has an advantage in that it is relatively simple in terms of manufacturing complexity, and individual component replacement is relatively easy. However, due to the relatively large size of the circuit board, it is not easy to secure battery capacity. For example, the conventional display device may have a second battery area BTRA2.

The display device according to an embodiment of the present disclosure includes the package element PCD. In the display device, the package element PCD, the display panel PN, and the circuit board CICB (or the display circuit board 300) are electrically connected to each other via the interlayer insulating film ILINSF. In an example in which a complex system is implemented in one package element PCD, miniaturization of the circuit board CICB (or the display circuit board 300) may be achieved. In particular, a space in which the battery may be physically disposed may be further secured. For example, the display device according to an embodiment may have a first battery area BTRA1.

The first battery area BTRA1 further has an additional battery area ADAR in addition to the second battery area BTRA2. A space in which the battery may be disposed may be further physically secured by the additional battery area ADAR, and accordingly, the use time of the display device may be improved. In some aspects, activation of a high-performance function and heat dissipation management of the display device may be further facilitated.

The display device according to an embodiment of the present disclosure includes the package element PCD including the plurality of chips CHP to implement a structure in which the plurality of chips CHP are arranged in one package in a dense manner. Accordingly, the physical size of the circuit board CICB (or the display circuit board 300) may be reduced, and the additional battery area ADAR may be secured.

When the display device includes the package element PCD, the display device according to an embodiment may further include the interlayer insulating film ILINSF electrically connected to the package element PCD. The interlayer insulating film ILINSF may be electrically connected to the circuit board CICB (or the display circuit board 300) and the display panel PN.

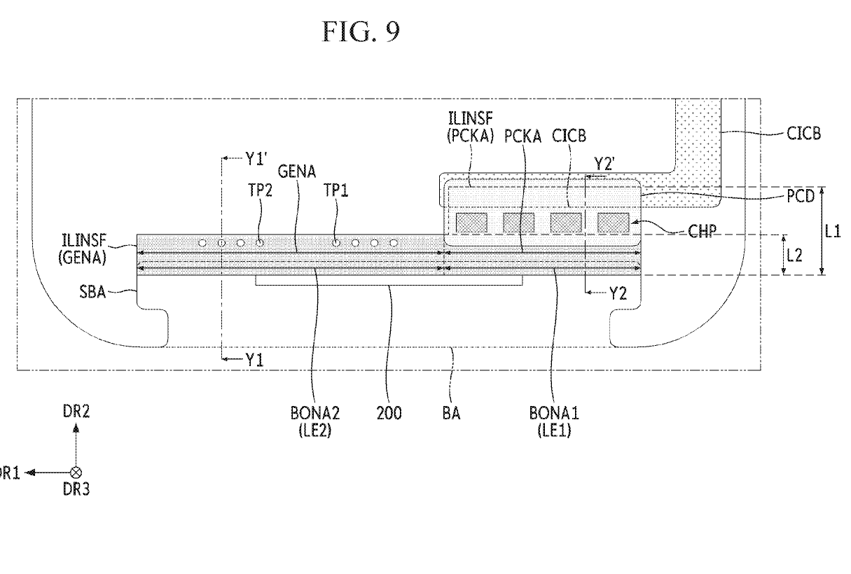

FIG. 9 is a partially enlarged view illustrating an area J of FIG. 7.

Referring to FIG. 9, in the bent state, the sub-area SBA may be connected to the interlayer insulating film ILINSF via a bonding area BONA1 and BONA2. The bonding area BONA1 and BONA2 may be an area in which the sub-area SBA and the interlayer insulating film ILINSF overlap each other in the third direction DR3 (or thickness direction).

The interlayer insulating film ILINSF may be divided into a plurality of areas. The interlayer insulating film ILINSF may include a plurality of areas extending in the first direction DR1 and the second direction DR2. The interlayer insulating film ILINSF may include a package area PCKA extending in the first direction DR1 and the second direction DR2, and a general area GENA disposed in the first direction DR1 from the package area PCKA.

An area in which the package area PCKA and the sub-area SBA overlap each other in the third direction DR3 (or the thickness direction) may be the first bonding area BONA1. An area where the general area GENA and the sub-area SBA overlap each other in the third direction DR3 (or thickness direction) may be the second bonding area BONA2. The package area PCKA may be electrically connected to the sub-area SBA via the first bonding area BONA1, and the general area GENA may be electrically connected to the sub-area SBA via the second bonding area BONA2.

The package element PCD may be mounted or disposed on the package area PCKA. The package area PCKA may be distinguished from the general area GENA in that the package area overlaps the package element PCD. The circuit board CICB may be further connected to the package area PCKA.

In an embodiment, the general area GENA may be formed such that the general area GENA extends in the first direction DR1. The package area PCKA may extend in the first direction DR1 and may extend so as to protrude in the second direction DR2. The package area PCKA may have a first width LE1 in the first direction DR1, and the general area GENA may have a second width LE2 in the first direction DR1. Accordingly, a length of the first bonding area BONA1 in the first direction DR1 may be the first width LE1, and a length of the second bonding area BONA2 in the first direction DR1 may be the second width LE2. In an embodiment, the first width LE1 may be smaller than the second width LE2. The package area PCKA is defined as an area where the package element PCD is disposed. Thus, the first width LE1 may be set in a corresponding manner to the length of the package element PCD in the first direction DR1.

The package area PCKA overlaps the package element PCD. Thus, the package area PCKA may include a bent portion. However, embodiments of the present disclosure are not limited thereto. Depending on the sizes of the interlayer insulating film ILINSF, the package element PCD, and the circuit board CICB, overlapping therebetween, a protruding relationship therebetween, or shapes thereof may be modified.

The package area PCKA may have a first length L1 in the second direction DR2, and the general area GENA may have a second length L2 in the second direction DR2. The second length L2 may be the same as or different from the first length L1. In an embodiment, the second length L2 may be smaller than the first length L1. Accordingly, the package area PCKA may be formed to have a shape protruding in the second direction DR2 or in a direction toward the circuit board CICB. The circuit board CICB may be attached to the protruding portion of the package area PCKA. That is, the protruding portion of the interlayer insulating film ILINSF may be disposed between the circuit board CICB and the package element PCD in the third direction DR3 (or thickness direction).

The general area GENA may include a plurality of test pads TP1 and TP2. The test pads TP1 and TP2 may include a first test pad TP1 and a second test pad TP2 spaced apart from the first test pad TP1. The test pads TP1 and TP2 may be used to evaluate Assembly Reliability Test (ART) between the interlayer insulating film ILINSF, the package element PCD, the sub-area SBA, and the circuit board CICB. That is, the test pads TP1 and TP2 may be parts which external probes (probe pins) are in contact with to evaluate adhesive quality, contact stability, durability against heat and/or humidity, and the like, after all of the interlayer insulating film ILINSF, the package element PCD, and the circuit board CICB are assembled with each other to be electrically connected to each other. Under the arrangement of the test pads TP1 and TP2, deterioration and failure of the display device are predicted, and environmental stress testing is executed, such that quality control of the display device may be facilitated.

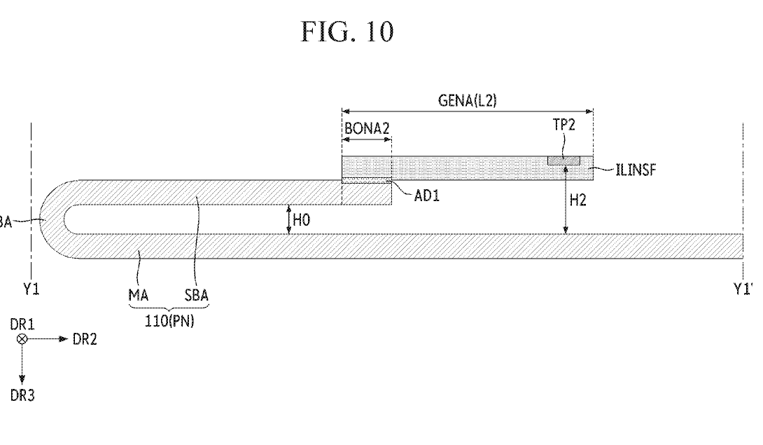

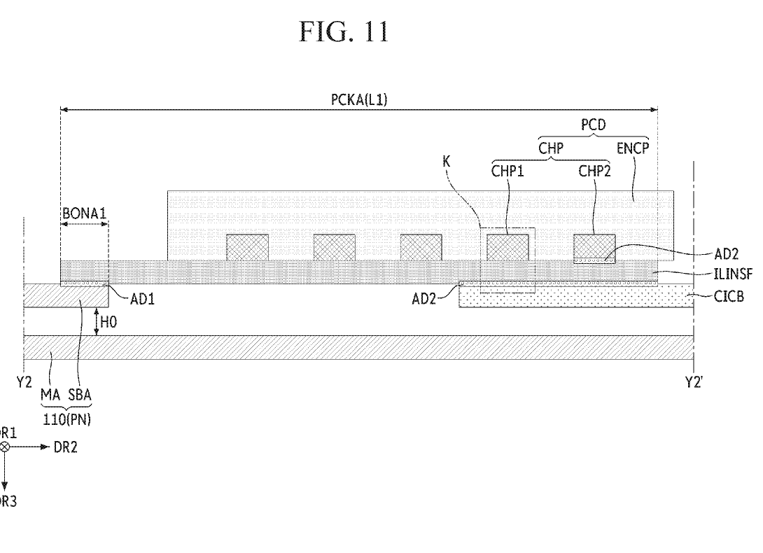

FIG. 10 is a cross-sectional view illustrating a portion taken along a line Y1-Y1' of FIG. 7. FIG. 11 is a cross-sectional view illustrating a portion taken along a line Y2-Y2' of FIG. 7.

Referring to FIGS. 9 and 10, in the bent state, the display panel PN may include the main area MA, the sub-area SBA, and the bendable area BA connecting the main area MA and the sub-area SBA to each other. A support member or the like may be further disposed in the separation space corresponding to a vertical distance H0 between the main area MA and the sub-area SBA so as to contact the sub-area SBA and the main area MA and support all thereof.

The sub-area SBA may be electrically connected to the interlayer insulating film ILINSF via a first adhesive member AD1. The illustrated cross-sectional view illustrates a portion corresponding to the general area GENA of the interlayer insulating film ILINSF, and thus the length of the interlayer insulating film ILINSF in the second direction DR2 may be the second length L2. The first adhesive member AD1 may include an anisotropic conductive film (ACF). The first adhesive member AD1 may be disposed in the second bonding area BONA2 and fix the interlayer insulating film ILINSF to the sub-area SBA.

The second test pad TP2 may be spaced by a second vertical length H2 from the main area MA. Although not illustrated, the first test pad TP1 may be spaced from the main area MA by a first vertical length. In an embodiment, the first vertical length and the second vertical length H2 may be equal to each other. In the display device according to embodiments of the present disclosure, the first test pad TP 1 and the second test pad TP 2 may be formed to be spaced by the same spacing from the main area MA.

If the first test pad TP1 and the second test pad TP2 are located at different vertical levels, for example, the first test pad TP1 is disposed in the second bonding area BONA2, there is a possibility that an error in the assembly reliability test may occur due to a difference between the vertical levels of the first test pad TP1 and the second test pad TP2. The display device according to the embodiment includes the first test pad TP1 and the second test pad TP2 positioned at the same vertical length, thereby improving the accuracy of the assembly reliability test.

Referring to FIGS. 9 and 11, the sub-area SBA may be electrically connected to the interlayer insulating film ILINSF via the first adhesive member AD1. The illustrated cross-sectional view illustrates a portion corresponding to the package area PCKA of the interlayer insulating film ILINSF, and thus, the length of the interlayer insulating film ILINSF in the second direction DR2 may be the first length L1. The first adhesive member AD1 may include an anisotropic conductive film (ACF). The first adhesive member AD1 may be disposed in the first bonding area BONA1 and fix the interlayer insulating film ILINSF to the sub-area SBA.

The package element PCD may be disposed on the package area PCKA of the interlayer insulating film ILINSF. The package element PCD may be disposed on the interlayer insulating film ILINSF. The package element PCD may be disposed on one surface of the interlayer insulating film ILINSF, and the circuit board CICB may be attached to the other surface of the interlayer insulating film ILINSF. In other words, the interlayer insulating film ILINSF may be disposed between the package element PCD and the circuit board CICB in the third direction DR3 (or thickness direction).

The circuit board CICB may be electrically connected to the interlayer insulating film ILINSF via the second adhesive member AD2. The circuit board CICB may be attached to the interlayer insulating film ILINSF via the second adhesive member AD2. The second adhesive member AD2 may include a metal. However, embodiments of the present disclosure are not limited thereto. In an embodiment, the metal may include tin (Sn) and lead (Pb) or lead-free solder (Sn-Ag-Cu). However, embodiments of the present disclosure are not limited thereto. For example, the interlayer insulating film ILINSF and the circuit board CICB may be connected to each other in a soldering manner. The soldering may be a scheme of melting a metal to bond the interlayer insulating film ILINSF and the circuit board CICB to each other. For example, the circuit board CICB may be connected to the interlayer insulating film ILINSF in the soldering manner.

The package element PCD disposed on one surface of the interlayer insulating film ILINSF may include the plurality of chips CHP and an encapsulant ENCP. The plurality of chips CHP may include the first chip CHP1, the second chip CHP2, and the like. However, embodiments of the present disclosure are not limited thereto. Examples of the first chip CHP1 and the second chip CHP2 are not limited to those described herein.

One chip CHP (e.g., the second chip CHP 2) of the package element PCD may be connected to the interlayer insulating film ILINSF via the second adhesive member AD2, and another chip CHP (e.g., the first chip CHP 1) may be electrically connected to the interlayer insulating film ILINSF using another connection method.

The encapsulant ENCP may be a component formed to encapsulate and fix the plurality of chips CHP. The encapsulant ENCP may protect the plurality of chips CHP from an external environment such as dust, moisture, impact, or the like, may transfer heat generated when the chip CHP operates to the outside to perform a heat dissipation function, may prevent electrical interference between the chip CHP and an external element, and may serve to mechanically fastening the plurality of chips CHP onto the interlayer insulating film ILINSF.

For example, the encapsulant ENCP may be an epoxy-based encapsulant. For example, the encapsulant ENCP may be an epoxy molding compound (EMC). The encapsulant ENCP may include an epoxy resin as a thermosetting polymer, a filler for improving thermal conductivity and mechanical strength, a curing agent for curing the epoxy resin, and an additive for controlling adhesion, fluidity, moisture resistance, and the like.

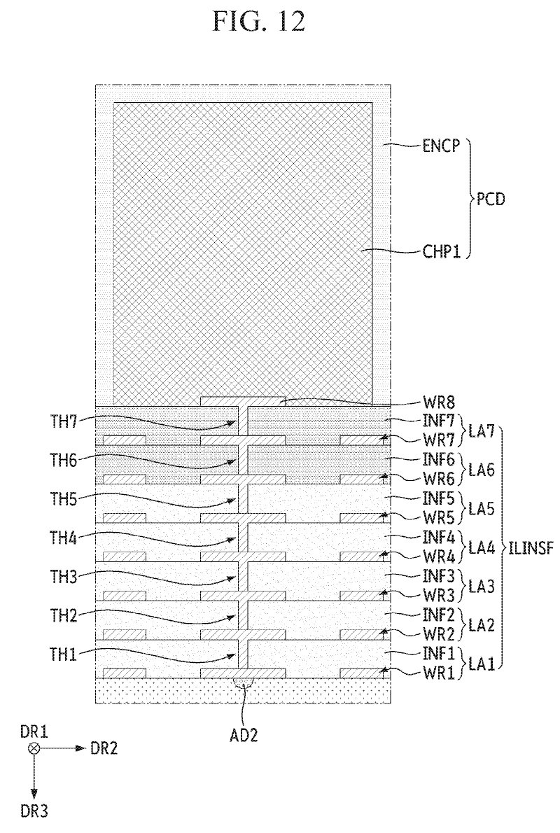

FIG. 12 is a partially enlarged view illustrating an area K of FIG. 11.

Referring to FIGS. 11 and 12, the interlayer insulating film ILINSF may be electrically connected to the circuit board CICB via the second adhesive member AD2. The package element PCD may be disposed on the interlayer insulating film ILINSF, and the first chip CHP 1 according to some embodiments may be electrically connected to the interlayer insulating film ILINSF in another connection method described herein.

The interlayer insulating film ILINSF may include a circuit wiring layer stack LA1, LA2, LA3, LA4, LA5, LA6, and LA7 including a plurality of wiring layers LA1, LA2, LA3, LA4, LA5, LA6, and LA7. The circuit wiring layer stack LA1, LA2, LA3, LA4, LA5, LA6, and LA7 may include the plurality of wiring layers LA1, LA2, LA3, LA4, LA5, LA6, and LA7 for electrically connecting the sub-area SBA and the package element PCD to each other or electrically connecting the sub-area SBA and the circuit board CICB to each other. The plurality of wiring layers LA1, LA2, LA3, LA4, LA5, LA6, and LA7 may include a first wiring layer LA1, a second wiring layer LA2, a third wiring layer LA3, a fourth wiring layer LA4, a fifth wiring layer LA5, a sixth wiring layer LA6, and a seventh wiring layer LA7. However, embodiments of the present disclosure are not limited thereto.

The plurality of wiring layers LA1, LA2, LA3, LA4, LA5, LA6, and LA7 may respectively include wirings WR1, WR2, WR3, WR4, WR5, WR6, and WR7, and insulating films WR1, WR2, WR3, WR4, WR5, WR6, WR7, and INF1 respectively covering the wirings INF2, INF3, INF4, INF5, INF6, and INF7. For example, the first wiring layer LA1 may include a first wiring WR1 and a first insulating film INF1 covering the first wiring WR1, the second wiring layer LA2 may include a second wiring WR2 and a second insulating film INF2 covering the second wiring WR2, the third wiring layer LA3 may include a third wiring WR3 and a third insulating film INF3 covering the third wiring WR3, the fourth wiring layer LA4 may include a fourth wiring WR4 and a fourth insulating film INF4 covering the fourth wiring WR4, the fifth wiring layer LA5 may include a fifth wiring WR5 and a fifth insulating film INF 5 covering the fifth wiring WR5, the sixth wiring layer LA6 may include a sixth wiring WR6 and a sixth insulating film INF6 covering the sixth wiring WR6, and the seventh wiring layer LA7 may include a seventh wiring WR7 and a seventh insulating film INF7 covering the seventh wiring WR7. As described herein, the circuit wiring layer stack LA1, LA2, LA3, LA4, LA5, LA6, and LA7 may be formed in a structure in which the wirings and the insulating films are repeatedly stacked in multiple layers to implement a high integrated circuit.

Each of the plurality of wirings WR1, WR2, WR3, WR4, WR5, WR6, and WR7 may include a metal. For example, the plurality of wirings WR1, WR2, WR3, WR4, WR5, WR6, and WR7 may be formed of copper. The plurality of wirings WR1, WR2, WR3, WR4, WR5, WR6, and WR7 may serve to transmit electrical signals in the circuit wiring layer stack LA1, LA2, LA3, LA4, LA5, LA6, and LA7.

Each of the plurality of insulating films INF1, INF2, INF3, INF4, INF5, INF6, and INF7 may include an epoxy resin-based insulating material. Each of the plurality of insulating films INF1, INF2, INF3, INF4, INF5, INF6, and INF7 may serve to prevent electrical interference between adjacent ones of the plurality of wirings WR1, WR2, WR3, WR4, WR5, WR6, and WR7 and to prevent leakage current therebetween.

The plurality of insulating films INF1, INF2, INF3, INF4, INF5, INF6, and INF7 include the same material in that they all include the epoxy-based insulating material. However, embodiments of the present disclosure are not limited thereto. The plurality of insulating films INF1, INF2, INF3, INF4, INF5, INF6, and INF7 may be grouped into two groups including different materials. In an embodiment, the first insulating film INF1, the second insulating film INF2, the third insulating film INF3, the fourth insulating film INF4, and the fifth insulating film INF5 may include the same material, while the sixth insulating film INF 6 and the seventh insulating film INF 7 may include the same material. For example, each of the first insulating film INF1, the second insulating film INF2, the third insulating film INF3, the fourth insulating film INF4, and the fifth insulating film INF5 may include an epoxy-based resin, a curing agent, and inorganic particles. Each of the sixth insulating film INF 6 and the seventh insulating film INF 7 may include an epoxy-based resin and glass fibers. Each of the sixth insulating film INF6 and the seventh insulating film INF7 may include a prepreg (Pre-impregnated Composite). The prepreg is cured in reaction with heat and pressure, and has excellent mechanical strength and electrical properties.

Through-holes TH1, TH2, TH3, TH4, TH5, TH6, and TH7 may be respectively formed in the plurality of insulating films INF1, INF2, INF3, INF4, INF5, INF6, and INF7. For example, a first through-hole TH1 may be formed in the first insulating film INF1, a second through-hole TH2 may be formed in the second insulating film INF2, a third through-hole TH3 may be formed in the third insulating film INF3, a fourth through-hole TH4 may be formed in the fourth insulating film INF4, a fifth through-hole TH5 may be formed in the fifth insulating film INF5, a sixth through-hole TH6 may be formed in the sixth insulating film INF6, and a seventh through-hole TH7 may be formed in the seventh insulating film INF7.

The plurality of wirings WR1, WR2, WR3, WR4, WR5, WR6, and WR7 may be electrically connected to each other via the through-holes TH1, TH2, TH3, TH4, TH5, TH6, and TH7 formed in the plurality of insulating films INF1, INF2, INF3, INF4, INF5, INF6, and INF7, respectively. An eighth wiring WR8 may be further disposed on the seventh insulating film INF7. The eighth wiring WR8 may electrically connect the first chip CHP1 of the package element PCD and the interlayer insulating film ILINSF to each other.

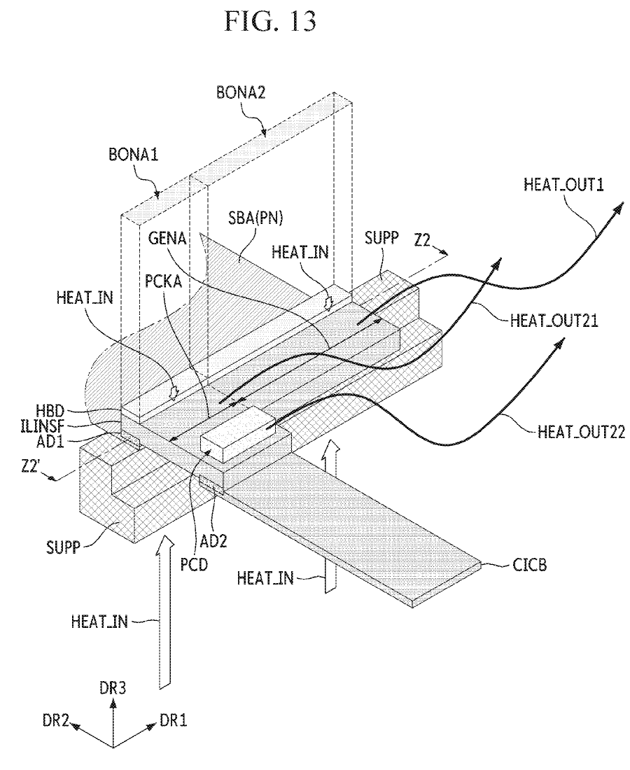

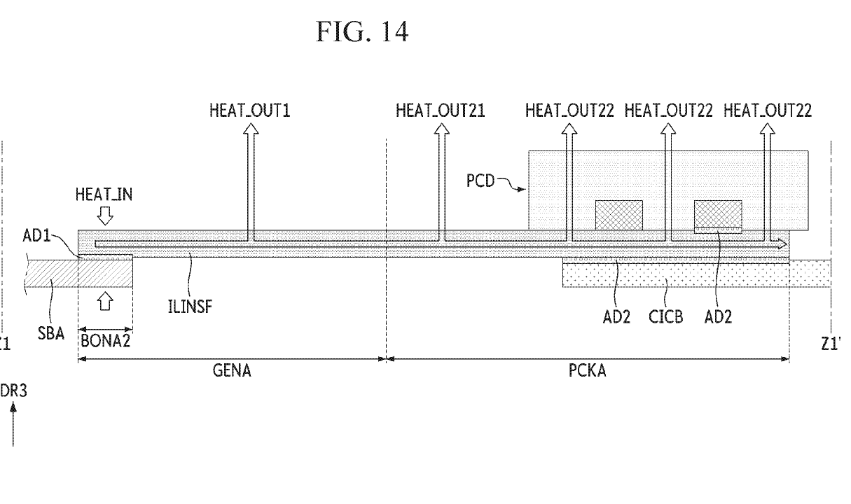

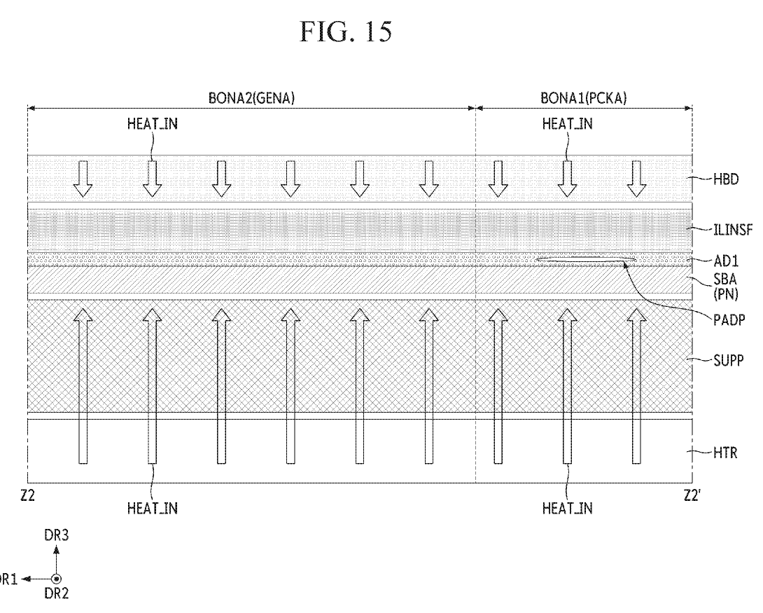

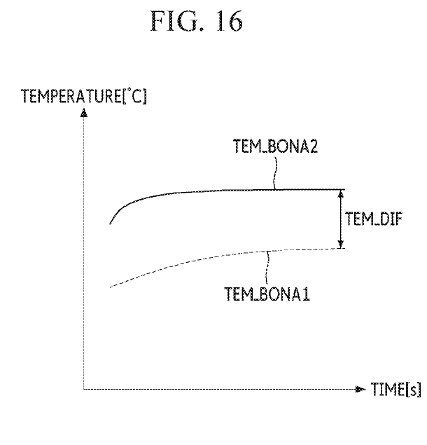

FIG. 13 is a perspective view schematically illustrating a process of manufacturing a display device according to an embodiment of the present disclosure. FIG. 14 is a cross-sectional view illustrating a portion taken along a line Z1-Z1' of FIG. 6. FIG. 15 is a cross-sectional view illustrating a portion taken along a line Z2-Z2' of FIG. 13. FIG. 16 is a graph illustrating a temperature of each of a first bonding area and a second bonding area over time.

Referring to FIGS. 13 to 16, the interlayer insulating film ILINSF to which the circuit board CICB and the package element PCD are attached may be adhered to the sub-area SBA in a thermal compression process. The thermal compression process between the interlayer insulating film ILINSF and the sub-area SBA may be performed by a manufacturing apparatus including a heater HTR, a support plate SUPP, and a thermal bonding device HBD. The heater HTR and the thermal bonding device HBD supplied-heat to the first adhesive member AD1 between the sub-area SBA and the interlayer insulating film ILINSF, and the thermal bonding device HBD applies pressure to the display panel PN and the interlayer insulating film ILINSF disposed on the support plate SUPP.

The conductive particles (or conductive particles in the anisotropic conductive film) in the first adhesive member AD1 may be disposed between and connected to the interlayer insulating film ILINSF and the display panel PN under supplied-heat HEAT_IN supplied from the thermal bonding device HBD to the first bonding area BONA1 and the second bonding area BONA2, and supplied-heat HEAT_IN transmitted from the heater HTR through the support plate SUPP to the first bonding area BONA1 and the second bonding area BONA2 on a side interlayer insulating film ILINSF on which the support plate SUPP is disposed.

When the interlayer insulating film ILINSF and the display panel PN are adhered to each other by the manufacturing apparatus, heat of an amount equal to or greater than a critical amount should be supplied to the first adhesive member AD1. In an example in which the heat is supplied to the display device, a temperature of the thermal bonding device HBD may be greater than a temperature of the support plate SUPP.

As described herein, the interlayer insulating film ILINSF may include the general area GENA and the package area PCKA. A length of the general area GENA in the second direction DR2 may be smaller than a length of the package area PCKA in the second direction DR2. The package element PCD may be disposed on the package area PCKA. In the interlayer insulating film ILINSF, the general area GENA and the package area PCKA may dissipate heat corresponding to the supplied-heat HEAT_IN. The general area GENA may dissipate first dissipated-heat HEAT_OUT1, and the package area PCKA may dissipate second dissipated-heat HEAT_OUT21 and third dissipated-heat HEAT_OUT22.

The package element PCD may be disposed on the package area PCKA. In an example in which the heat is supplied to the display device, the package element PCD may function as a heat sink. In an embodiment, a surface heat loss rate W/m² may be greater in the package element PCD than in the interlayer insulating film ILINSF.

Accordingly, the first adhesive member AD1 (or anisotropic conductive film) of the first bonding area BONA1 may not sufficiently receive the heat. In other words, the supplied-heat HEAT_IN transferred to the first bonding area BONA1 and the supplied-heat HEAT_IN transferred to the second bonding area BONA2 may have the same amount per unit area or unit volume. However, due to the third dissipated-heat HEAT_OUT22 from the package element PCD, the amount of heat ultimately transferred to the first bonding area BONA1 may be different from the amount of heat ultimately transferred to the second bonding area BONA2. In detail, the third dissipated-dissipated-heat HEAT_OUT22 is greater than each of the second dissipated-dissipated-heat HEAT_OUT21 and the first dissipated-dissipated-heat HEAT_OUT1, the amount of heat ultimately transferred to the first bonding area BONA1 may be smaller than the amount of heat ultimately transferred to the second bonding area BONA2.

Accordingly, the temperature of the general area GENA may be higher than the temperature of the package area PCKA. A temperature difference TEM_DIF may occur between the general area GENA and the package area PCKA due to an imbalance between the amounts of heat ultimately transferred thereto (see FIG. 16). A temperature graph TEM_BONA1 of the first bonding area BONA1 increases over time in a temperature range lower than a temperature graph TEM_BONA2 of the second bonding area BONA2.

The amount of heat transferred through the thermal bonding device HBD and the support plate SUPP may be designed without considering the third dissipated-heat HEAT_OUT22. In this case, as a result, a sufficient amount of heat may not be transferred to the first adhesive member AD1 corresponding to the first bonding area BONA1. Accordingly, a poor adhesion or adhesion defect PADP may occur in the first adhesive member AD1 corresponding to the first bonding area BONA1. The adhesion defect PADP may cause non-uniformity in the compression quality between the first bonding area BONA1 and the second bonding area BONA2 arranged with each other in the second direction DR2, and further, may cause a problem of deteriorating the operational reliability of the display device (e.g., a resistance variation along an area of the cured first adhesive member AD1).

In order to solve such a problem, the amount of the supplied-heat HEAT_IN supplied from the thermal bonding device HBD and the amount of the supplied-heat HEAT_IN transferred through the support plate SUPP may be increased. In an example in which the amount of the supplied-heat HEAT_IN is increased, the temperature of the first bonding area BONA1 will increase, but accordingly, the temperature of the general area GENA in which the heat dissipation plate or the heat sink does not exist also increases. As a result, a greater amount of heat than the amount of heat for curing the first adhesive member AD1 may be supplied to the general area GENA in which the heat dissipation plate or the heat sink does not exist. In this case, the temperature imbalance between the first bonding area BONA1 and the second bonding area BONA2 may still exist.

The present disclosure may propose a means for solving the temperature imbalance between the general area GENA having a relatively high temperature because there is no component for performing a function of the heat dissipation plate or heat sink therein, and the package area PCKA having a relatively low temperature because there is the package element PCD for performing the function of the heat dissipation plate or heat sink therein. According to various embodiments disclosed herein, the curing of the first adhesive member AD1 between the display panel PN and the interlayer insulating film ILINSF may be uniform across the first bonding area BONA1 and the second bonding area BONA2. Accordingly, the compression quality of the bonding area BONA1 and BONA2 may be improved, and the operational reliability of the display device may be improved.

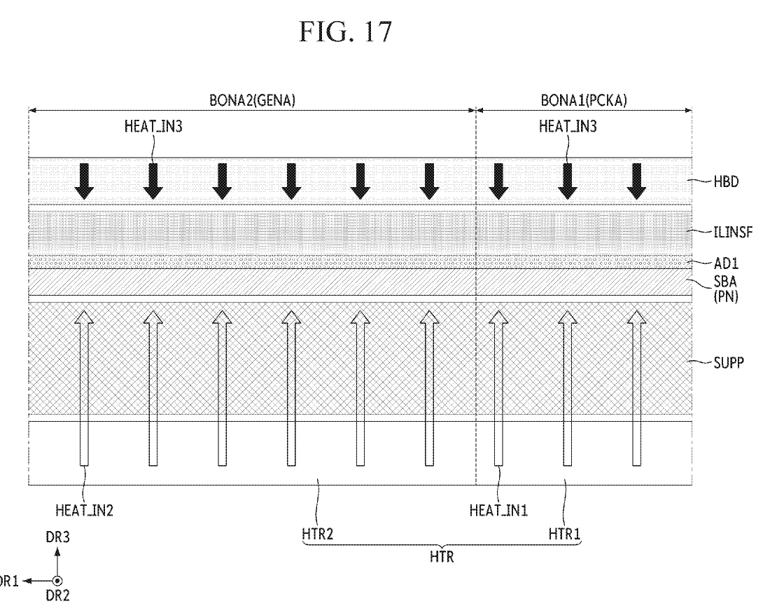

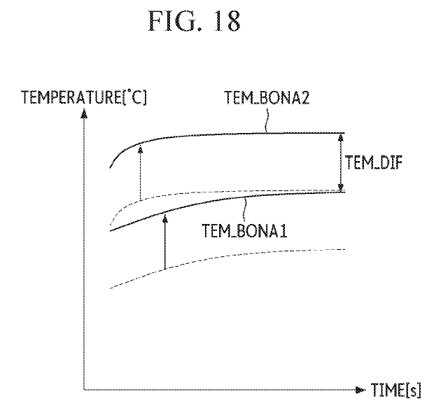

FIG. 17 is a cross-sectional view illustrating a manufacturing process of a display device according to an embodiment of the present disclosure. FIG. 18 is a graph illustrating a temperature of each of a first bonding area and a second bonding area over time when a display device is manufactured as illustrated in FIG. 17.

Referring to FIGS. 17 and 18, in order to reduce the adhesion defect of the first adhesive member AD1 disposed in the first bonding area BONA1, the amount of heat transferred to the first adhesive member AD1 from the thermal bonding device HBD and the heater HTR may be increased.

The apparatus for manufacturing the display device according to an embodiment may include the thermal bonding device HBD, the support plate SUPP, and the heater HTR. The heater HTR may include a first heater HTR1 and a second heater HTR2. The first heater HTR1 may be formed at a position corresponding to the first bonding area BONA1, and the second heater HTR2 may be formed at a position corresponding to the second bonding area BONA2.

The first heater HTR1 may transfer first supplied-heat HEAT_IN1 to the support plate SUPP. The second heater HTR2 may transfer second supplied-heat HEAT_IN2 to the support plate SUPP. The thermal bonding device HBD may transfer third supplied-heat HEAT_IN3 to the first adhesive member AD1. The thermal bonding device HBD may include a portion formed to correspond to the first bonding area BONA1 and a portion formed to correspond to the second bonding area BONA2. The amount of heat per unit area (or per unit volume) transferred from the thermal bonding device HBD to each of the first bonding area BONA1 and the second bonding area BONA2 may be an amount of the third supplied-heat HEAT_IN3 and thus the amount of heat per unit area (or per unit volume) transferred from the thermal bonding device HBD to the first bonding area BONA1 and the amount of heat per unit area (or per unit volume) transferred from the thermal bonding device HBD to the second bonding area BONA2 may be equal to each other. However, embodiments of the present disclosure are not limited thereto.

The temperature of the first heater HTR1, the second heater HTR2, and the thermal bonding device HBD may increase due to the first supplied-heat HEAT_IN1, the second supplied-heat HEAT_IN2, and the third supplied-heat HEAT_IN3. Since the first supplied-heat HEAT_IN1 and the second supplied-heat HEAT_IN2 are transferred to the first adhesive member AD1 via the support plate SUPP, the temperature of the support plate SUPP may also increase when the heat is supplied to the first adhesive member AD1.

Since the support plate SUPP transferring the heat is distinguished from the thermal bonding device HBD generating the heat, the temperature of the support plate SUPP may be lower than the temperature of the thermal bonding device HBD when heat is supplied to the first adhesive member AD1. Specifically, when heat is supplied to the first adhesive member AD1, the temperature of the support plate SUPP may be lower than 100 degrees Celsius (or lower than 80 degrees Celsius), and the temperature of the thermal bonding device HBD may be 200 degrees Celsius or higher. However, embodiments of the present disclosure are not limited thereto.

In the first embodiment, increasing the amount of heat transferred to the first adhesive member AD1 may result in removal of the adhesion defect of the first adhesive member AD1 disposed in the first bonding area BONA1. A component or member that transfers heat is the heater HTR and the thermal bonding device HBD. In the apparatus for manufacturing the display device according to a first embodiment, increasing the amount of heat per unit area (or per unit volume) transferred via the thermal bonding device HBD may reduce or eliminate the adhesion defect in the first bonding area BONA1and improve the compression quality therein. That is, increasing the third supplied-heat HEAT_IN3 may reduce or prevent the adhesion defect of the first bonding area BONA1. More specifically, when the third supplied-heat HEAT_IN3 having increased to solve the adhesion defect is transferred to the first adhesive member AD1, the temperature of the thermal bonding device HBD may be 200 degrees Celsius or higher.

However, when the amount of heat transferred via the thermal bonding device HBD is increased, the increased heat may also be transferred to the second bonding area BONA2. The third supplied-heat HEAT_IN3 may be transferred not only to the first bonding area BONA1 but also to the second bonding area BONA2.

Referring to FIG. 18, the temperature graph TEM_BONA1 of the first bonding area BONA1 may increase to the extent adjusted such that the adhesion defect of the first adhesive member AD1 is eliminated due to the increased third supplied-heat HEAT_IN3. However, there is a problem that the temperature graph TEM_BONA2 of the second bonding area BONA2 also increases due to the increased third supplied-heat HEAT_IN3. The first adhesive member AD1 of the second bonding area BONA2 is sufficiently cured only by the third supplied-heat HEAT_IN3. However, as the increased third supplied-heat HEAT_IN3 is transmitted thereto to solve the adhesion defect of the first bonding area BONA1, the temperature graph TEM_BONA2 of the second bonding area BONA2 also increases. In this case, there may still be a temperature difference TEM_DIF between the first bonding area BONA1 and the second bonding area BONA2.

As described herein, even when the third supplied-heat HEAT_IN3 is increased to solve the adhesion defect of the first bonding area BONA1, a temperature imbalance between the first bonding area BONA1 and the second bonding area BONA2 may still exist. Due to this imbalance, there may still be an imbalance in the compression quality between the first and second bonding areas, and there is a problem that the operational reliability of the display device is not sufficiently improved.

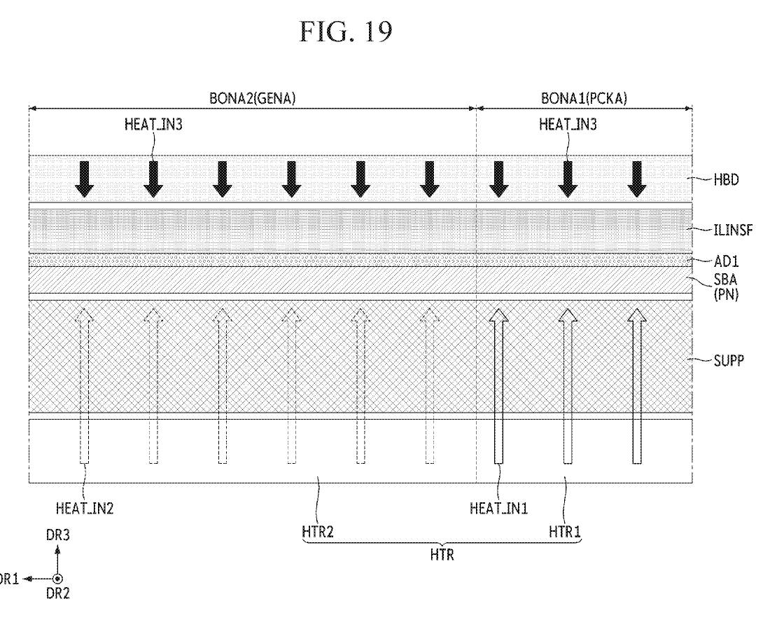

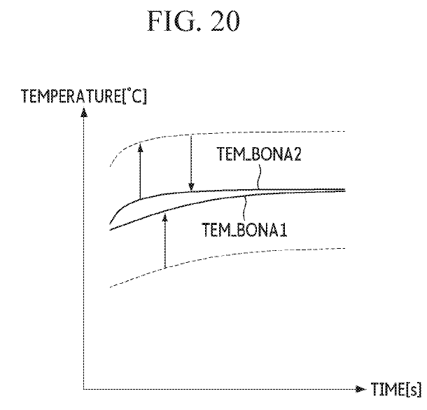

FIG. 19 is a cross-sectional view illustrating an apparatus for manufacturing a display device according to a first embodiment of the present disclosure. FIG. 20 is a graph illustrating a temperature of each of a first bonding area and a second bonding area over time when a display device is manufactured as illustrated in FIG. 19.

Referring to FIGS. 19 and 20, when the increased third supplied-heat HEAT_IN3 is transferred to the first adhesive member AD1, the first supplied-heat HEAT_IN1 and the second supplied-heat HEAT_IN2 may be different from each other. The first heater HTR1 may transmit the first supplied-heat HEAT_IN1 to a portion of the first adhesive member AD1 corresponding to the first bonding area BONA1, and the second heater HTR2 may transmit the second supplied-heat HEAT_IN2 to a portion of the first adhesive member AD1 corresponding to the second bonding area BONA2.

Although the third supplied-heat HEAT_IN3 is increased to solve the curing defect of the first bonding area BONA1, a problem may occur in that the temperature of the second bonding area BONA2 is increased to an extent than necessary or desired. The manufacturing apparatus according to the first embodiment of the present disclosure has an advantage in that an imbalance between an amount of heat transferred to the first adhesive member AD1 via the first heater HTR1 and an amount of heat transferred to the first adhesive member AD1 via the second heater HTR2 is induced, thereby securing operational reliability of the display device.

Since the first bonding area BONA1 corresponds to the package area PCKA and the second bonding area BONA2 corresponds to the general area GENA, a problem of temperature imbalance between the first and second bonding areas and deterioration of compression quality of the first bonding area BONA1 may occur due to the heat dissipation effect of the package element PCD disposed on the package area PCKA.

The manufacturing apparatus according to the first embodiment is configured to increase the third supplied-heat HEAT_IN3 to improve the compression quality of the first bonding area BONA1 and transmit the first supplied-heat HEAT_IN1 and the second supplied-heat HEAT_IN2 in different amounts to resolve the temperature imbalance between the first and second bonding areas.

In an embodiment, the temperature graph TEM_BONA2 of the second bonding area BONA2 may be lowered, without reducing the temperature graph TEM_BONA1 of the first bonding area BONA1. For this reason, the second supplied-heat HEAT_IN 2 may be smaller than the first supplied-heat HEAT_IN1. That is, when heat is supplied to the first adhesive member AD1, the amount of heat supplied to the first bonding area BONA1 from the first heater HTR 1 may be greater than the amount of heat supplied to the second bonding area BONA2 from the second heater HTR 2.

In this way, the imbalance between the first supplied-heat HEAT_IN1 and the second supplied-heat HEAT_IN2 is induced, such that the temperature of the portion of the support plate SUPP through which the first supplied-heat HEAT_IN1 passes and the temperature of the portion of the support plate SUPP through which the second supplied-heat HEAT_IN2 passes may be different from each other.

The support plate SUPP may be divided into a first support plate overlapping the first bonding area BONA1 in the third direction DR3 (or thickness direction) and a second support plate overlapping the second bonding area BONA2 in the third direction DR3 (or thickness direction). The first support plate SP1 may support the first bonding area BONA1, and the second support plate SP2 may support the second bonding area BONA2. The first supplied-heat HEAT_IN1 may be transferred via the first support plate to the first bonding area BONA1, and the second supplied-heat HEAT_IN2 may be transferred via the second support plate to the second bonding area BONA2. In an embodiment, the first supplied-heat HEAT_IN1 and the second supplied-heat HEAT_IN2 are different from each other. Thus, when heat is transferred to the first adhesive member AD1, temperatures of the first support plate SP1 and the second support plate SP2 may be different from each other. In some embodiments, the temperature of the first support plate SP1 may be lower than the temperature of the second support plate SP2.

Referring to FIG. 20, the temperature graph TEM_BONA2 of the second bonding area BONA2 may be lowered due to the transfer of the second supplied-heat HEAT_IN2 smaller than the first supplied-heat HEAT_IN1 thereto. As described herein, the manufacturing apparatus according to various embodiments of the present disclosure may improve the compression quality of the first bonding area BONA1 and at the same time, induce the balance between temperatures of the first bonding area BONA1 and the second bonding area BONA2.

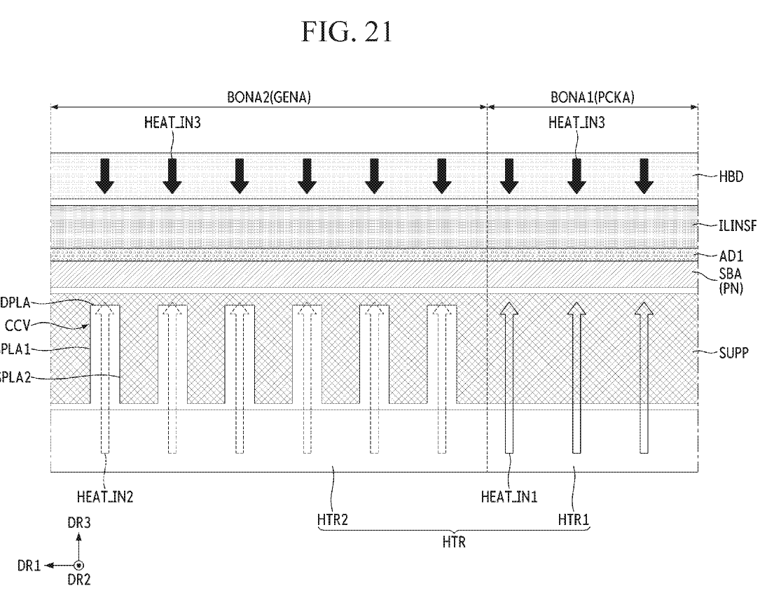

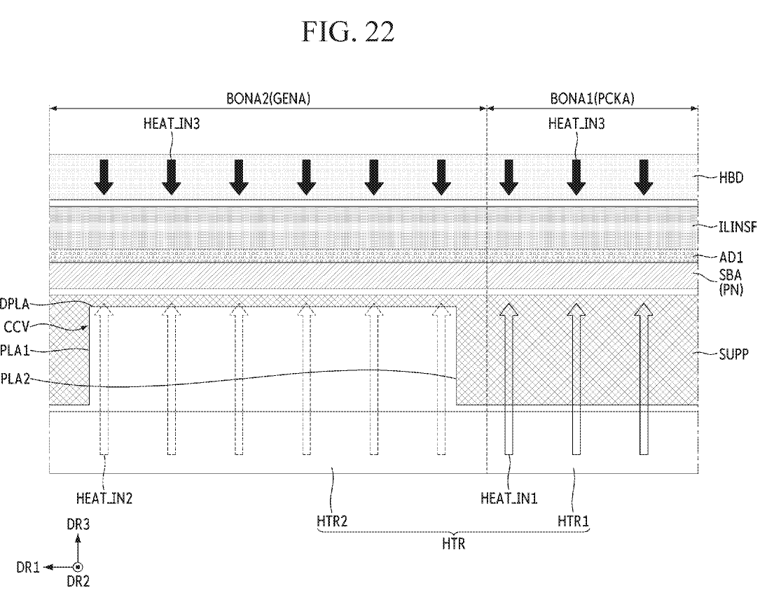

FIG. 21 is a cross-sectional view illustrating an apparatus for manufacturing a display device according to a second embodiment of the present disclosure. FIG. 22 is a modified example of FIG. 21.

Referring to FIGS. 21 and 22, in order to sufficiently lower the temperature of the first bonding area BONA1, the support plate SUPP may further include a recess CCV defined therein that performs a heat dissipation function.

Although the first supplied-heat HEAT_IN1 is adjusted to be smaller than the second supplied-heat HEAT_IN2, the temperature of the second bonding area BONA2 may still be higher than necessary or desired, due to the increased third supplied-heat HEAT_IN3 to improve the compression quality of the first bonding area BONA1.

In this case, the support plate SUPP of the manufacturing apparatus according to the embodiments of the present disclosure may be formed to further include the recess CCV defined therein. The recess CCV may be formed to increase a surface area per unit volume of the support plate SUPP.

The support plate SUPP may be divided into the first support plate corresponding to the first bonding area BONA1 and the second support plate corresponding to the second bonding area BONA2. The first bonding area BONA1 corresponds to the package area PCKA. In the package area PCKA, the package element PCD exhibits a heat dissipation effect, such that the apparatus may be implemented without features for further reducing the temperature in the package area PCKA. Accordingly, the first support plate SP1 may be implemented without the recess CCV.

The second support plate corresponds to the second bonding area BONA2 having a temperature graph higher than necessary or desired. The heat is transferred to the outside through the surface. As the surface area increases, the number of paths through which heat can escape (or be released) to the outside increases, thereby increasing heat dissipation efficiency. Like a heat dissipation plate HDP having a fin structure and thus an increased surface area per unit volume, the second support plate may be formed to include a plurality of recesses CCV corresponding to the fin structure. The recess CCV may include a first side surface SPLA1, a second side surface SPLA2, and a lower surface DPLA. In an example in which the recess CCV is formed in the second support plate, a path through which heat may be released or dissipate to the outside may be secured by the first side surface SPLA1 and the second side surface SPLA2 in addition to the lower surface DPLA, and thus heat dissipation efficiency may be increased.

In the manufacturing apparatus according to the second embodiment, the recess CCV may be formed in the second support plate corresponding to the second bonding area BONA2 to increase the surface area, and as a result, a temperature drop of the second bonding area BONA2 may be induced.

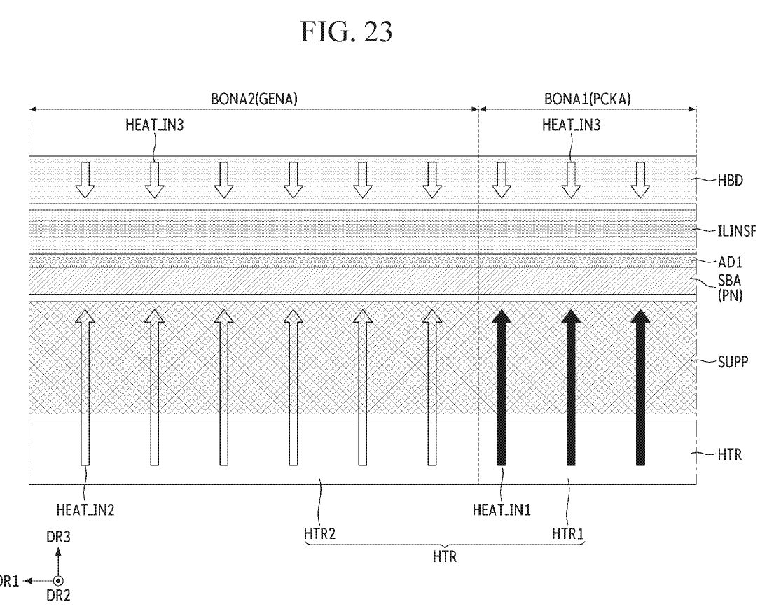

FIG. 23 is a cross-sectional view illustrating an apparatus for manufacturing a display device according to a third embodiment of the present disclosure.

Referring to FIG. 23, the adhesion defect and the imbalance between the compression quality may be removed by simply increasing the first supplied-heat HEAT_IN1, without increasing other heat (e.g., the second supplied-heat HEAT_IN2, the third supplied-heat HEAT_IN3).

Since the heat supplied via the heater HTR passes through the support plate SUPP, an greater amount of heat than an amount of the third supplied-heat HEAT_IN3 in the manufacturing apparatus according to the first embodiment or the second embodiment needs to be supplied via the first heater HTR1 in order to solve the adhesion defect by increasing the first supplied-heat HEAT_IN1 without adjusting the third supplied-heat HEAT_IN3.

This will be described again. The temperature of the support plate SUPP may be lower than the temperature of the thermal bonding device HBD. Since the manufacturing apparatus includes the support plate SUPP supporting the display panel PN, and the heat transferred to the first adhesive member AD1 via the heater HTR passes through the support plate SUPP, a path through which the heat supplied via the heater HTR flows is longer than a path through which the heat supplied via the thermal bonding device HBD flows. As the length of the flow path of the heat increases, the possibility of heat loss increases. That is, in solving the adhesion defect of the first adhesive member AD1 by increasing the supplied-heat HEAT_IN, the adhesion defect solving effect due to the increase of the first supplied-heat HEAT_IN1 or the second supplied-heat HEAT_IN2 may be smaller than the adhesion defect solving effect due to the increase of the third supplied-heat HEAT_IN3. Therefore, in order to solve the adhesion defect by simply increasing the first supplied-heat HEAT_IN1, an increase in an amount of heat greater than an increase in an amount of the third supplied-heat HEAT_IN3 when the adhesion defect is solved by increasing the third supplied-heat HEAT_IN3 is desired.

Accordingly, the first embodiment and the second embodiment may be more preferable than the third embodiment. However, the embodiments of the present disclosure are not limited thereto. In an example in which the thickness of the support plate SUPP is sufficiently small to maintain the support performance while reducing a length of the heat flow path, or when the material of the support plate SUPP is changed to a material having low heat loss, embodiments of the present disclosure may include increasing the first supplied-heat HEAT_IN1 to solve the adhesion defect and the temperature imbalance, without increasing other heat (e.g., the second supplied-heat HEAT_IN2, the third supplied-heat HEAT_IN3).

According to a technical purpose of the present disclosure, a temperature imbalance between the first bonding area BONA1 and the second bonding area BONA2 should be resolved while increasing the temperature of the first bonding area BONA1. The manufacturing apparatus includes the support plate SUPP, and the thermal bonding device HBD supplies the heat more directly than the heater HTR supplies the heat. For this reason, using the manufacturing apparatus, it is relatively easy to increase the first supplied-heat HEAT_IN1 transferred via the thermal bonding device HBD in order to preferentially solve the adhesion defect.

However, raising only the temperature of the thermal bonding device HBD is not suitable for resolving the imbalance. For this reason, one or more embodiments of the present disclosure may include preferably using the first heater HTR1 and the second heater HTR2 in a separate manner to induce the heat loss or the thermal dissipation effect in the second bonding area BONA2, without inducing the heat loss or the thermal dissipation effect in the first bonding area BONA1.

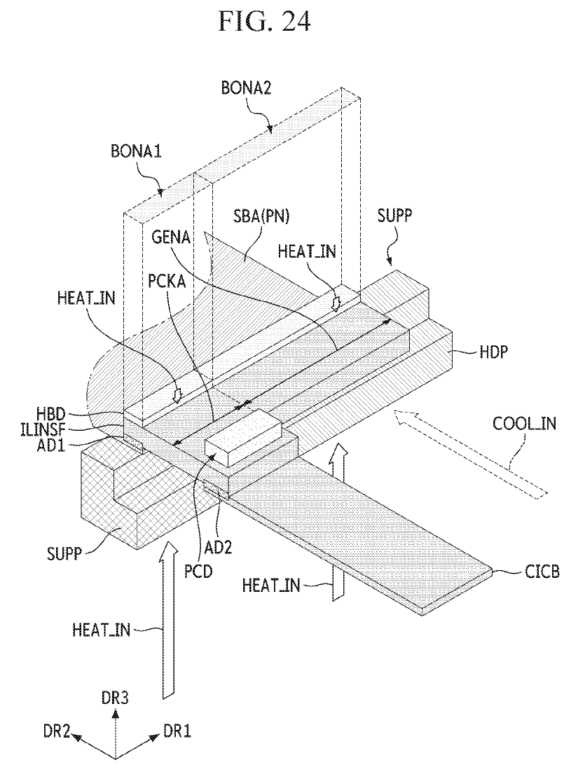

FIG. 24 is a perspective view illustrating an apparatus for manufacturing a display device according to a fourth embodiment of the present disclosure.

Referring to FIG. 24, the manufacturing apparatus may further include the heat dissipation plate HDP disposed on the first support plate corresponding to the first bonding area BONA1. At the same time, the manufacturing apparatus may be configured to supply cold air COOL_IN to the first adhesive member AD1. In this case, the supplied-heat HEAT_IN should be increased to such an extent that a portion of the first adhesive member AD1 overlapping the first bonding area BONA1 can be sufficiently cured. At the same time, since the temperature of the second bonding area BONA2 also increases, the supplied cold air COOL_IN may be supplied and the heat dissipation plate HDP of the support plate SUPP disposed to lower the temperature of the portion of the first adhesive member AD1 corresponding to the second bonding area BONA2.

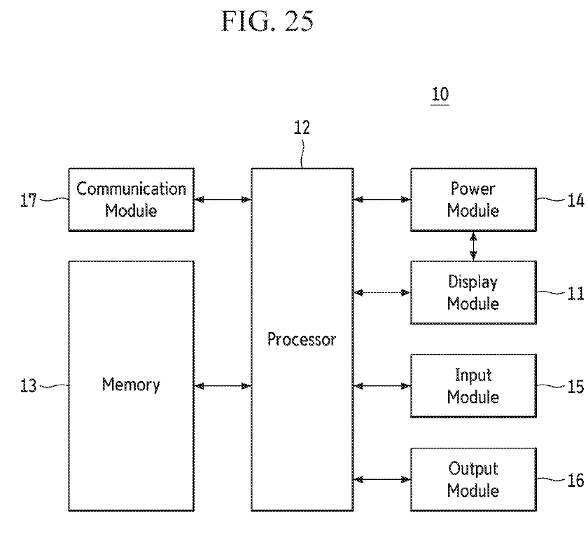

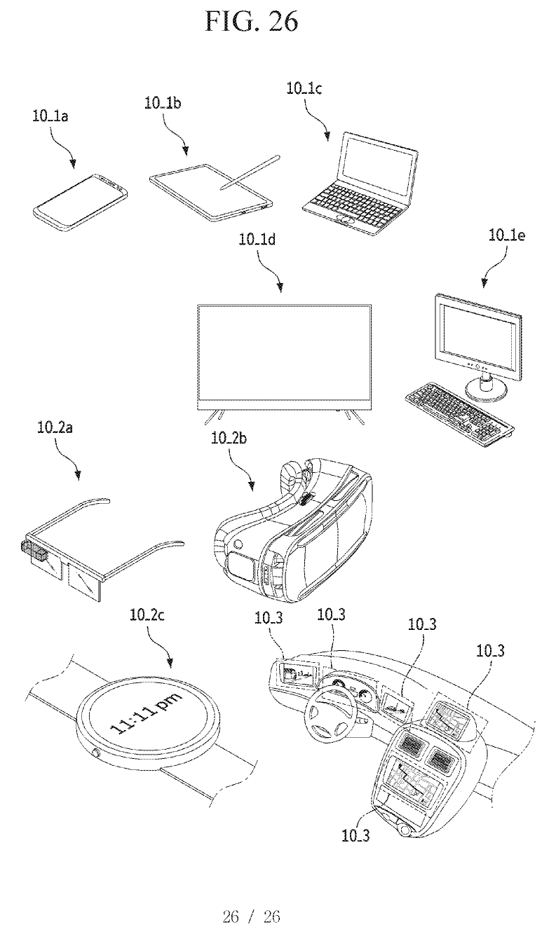

FIG. 25 is a block diagram of an electronic device according to an embodiment of the present disclosure. FIG. 26 is schematic views of an electronic device according to various embodiments of the present disclosure.

Referring to FIG. 25, the electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

Data information supportive of the operation of the processor 12 or the display module 11 may be stored in the memory 13. In an example in which the processor 12 executes an application stored in the memory 13, an image data signal and/or an input control signal may be transmitted to the display module 11, and the display module 11 may process the received signal to output image information on a display screen.

The power module 14 may include a power supply module such as a power adapter or a battery device. The power module 14 may include a power conversion module. The power conversion module may convert power supplied from the power supply module to generate power for the operation of the electronic device 10.

At least one of the above-described components of the electronic device 10 may be included in the display device according to the above-described embodiments. In some aspects, some of individual modules functionally included in one module may be included in the display device, and the others of the individual modules may be provided separately from the display device. For example, the display device may include the display module 11, while each of the processor 12, the memory 13, and the power module 14 may be provided in a form of another device in the electronic device 10 other than the display device.

The electronic device 10 may further include an input module 15, a non-image output module 16, and/or a communication module 17.

The input module 15 may provide input information to the processor 12 and/or the display module 11. The input module 15 may include various sensor modules as well as physical buttons, keyboards, and microphones. Examples of the sensor module may include a touch sensor, a pressure sensor, a distance sensor, a position sensor, a digitizer, a motion recognition sensor, a camera sensor, a light receiving sensor, a photoelectric conversion sensor, a temperature sensor, and a biometric sensor such as a blood pressure sensor, a blood glucose sensor, an electrocardiogram sensor, a heart rate sensor, and the like.

The non-image output module 16 may serve to receive information other than the image received from the processor 12 and provide the received information to the user. Examples of the non-image output module 16 may include a sound module, a haptic module, a light-emitting module, and the like, and may include other unique functional modules (e.g., a cooling module of a refrigerator, and the like) of the electronic device.

The communication module 17 is a module in charge of transmitting and receiving information between the electronic device 10 and an external device, and may include a receiver and a transmitter. The communication module 17 may include various wireless communication modules such as a mobile communication module, a Wi-Fi module, and a Bluetooth module, or various wired communication modules.

Referring to FIG. 26, various electronic devices to which the display device according to embodiments of the present disclosure is applied may include an electronic device for displaying an image, such as a smartphone 10_1a, a tablet PC 10_1b, a laptop 10_1c, a TV 10_1d, and a desk monitor 10_1e. In some aspects, various electronic devices to which the display device according to the embodiments of the present disclosure is applied may include a wearable electronic device including the display module such as smart glasses 10_2a, a head mounted display 10_2b, and a smart watch 10_2c, or a vehicle electronic device 10_3 including the display module such as a dashboard of a vehicle, a center fascia, a center information display (CID) disposed on a dashboard, and a room mirror display.

Although embodiments of the disclosure have been described herein with reference to the accompanying drawings, it will be understood by those having ordinary skill in the technical field to which the disclosure belongs that the disclosure may be practiced in other specific forms without altering the technical idea or essential features of the disclosure. It should therefore be understood that the embodiments described herein are examples in all respects and are not intended to be limiting.

What is claimed is:

1. An apparatus for manufacturing a display device, the apparatus comprising:
a first heater which supplies heat to a first bonding area of the display device; and
a second heater which supplies heat to a second bonding area of the display device,
wherein:
the display device comprises:
a display panel comprising a main area comprising a display area and a sub-area protruding from a side of the main area;
an interlayer insulating film attached onto the sub-area; and
a package element disposed on the interlayer insulating film,
the interlayer insulating film comprises a package area and a general area arranged with each other in a first direction,
the package element is disposed on the package area of the interlayer insulating film,
in the first bonding area, the package area and the sub-area overlap each other in a thickness direction of the display panel, and
in the second bonding area, the general area and the sub-area overlap each other in the thickness direction of the display panel.

2. The apparatus of claim 1, further comprising a thermal bonding device which supplies heat to the first bonding area and the second bonding area.

3. The apparatus of claim 2, wherein when the heat is supplied from the thermal bonding device to the display device, the interlayer insulating film is disposed between the first heater and the thermal bonding device.

4. The apparatus of claim 3, wherein when the heat is supplied from the thermal bonding device to the display device, the interlayer insulating film is disposed between the second heater and the thermal bonding device.

5. The apparatus of claim 1, further comprising a support plate which:
transfers the heat supplied from the first heater and the heat supplied from the second heater to the display device, and
supports the display device.

6. The apparatus of claim 5, wherein when the heat from the first heater is supplied to the display device, the support plate is disposed between the first heater and the display panel.

7. The apparatus of claim 6, wherein when the heat from the second heater is supplied to the display device, the support plate is disposed between the second heater and the display panel.

8. The apparatus of claim 1, wherein when the heat from the first heater and the heat from the second heater are supplied to the display device, an amount of the heat supplied from the first heater to the first bonding area is different from an amount of the heat supplied from the second heater to the second bonding area.

9. The apparatus of claim 8, wherein when the heat from the first heater and the heat from the second heater are supplied to the display device, an amount of heat supplied from the first heater to the first bonding area is greater than an amount of heat supplied from the second heater to the second bonding area.

10. The apparatus of claim 1, wherein:
the first bonding area has a first width in the first direction,
the second bonding area has a second width in the first direction, and
the first width is smaller than the second width.

11. The apparatus of claim 5, wherein the support plate comprises:
a first support plate supporting a portion of the display panel overlapping the first bonding area; and
a second support plate supporting a portion of the display panel overlapping the second bonding area,
wherein a surface area per unit volume of the first support plate is smaller than a surface area per unit volume of the second support plate.

12. The apparatus of claim 11, wherein the second support plate comprises a recess defined in the thickness direction.

13. The apparatus of claim 2, wherein:
the display device further comprises an anisotropic conductive film disposed between the display panel and the interlayer insulating film,
the first heater supplies heat to an area in which the anisotropic conductive film and the first bonding area overlap each other in the thickness direction,
the second heater supplies heat to an area in which the anisotropic conductive film and the second bonding area overlap each other in the thickness direction.

14. The apparatus of claim 5, further comprising a thermal bonding device which supplies heat to the first bonding area and the second bonding area,
wherein when the heat is supplied from the thermal bonding device to the display device, a temperature of the thermal bonding device is greater than a temperature of the support plate.

15. The apparatus of claim 9, wherein when the heat from the first heater and the heat from the second heater are supplied to the display device, a surface heat loss rate of the package area is greater than a surface heat loss rate of the general area.

16. An electronic device comprising:
a processor which provides an image signal;
a display module which receives the image signal from the processor and displays an image; and
a power module which supplies power to the display module,
wherein:
the display module comprises:
a display panel comprising a main area comprising a display area and a sub-area protruding from a side of the main area in a plan view;
an interlayer insulating film attached onto the sub-area using an apparatus for manufacturing a display device; and
a package element disposed on the interlayer insulating film,
the apparatus for manufacturing the display device comprises:
a first heater which supplies heat to a first bonding area of the display module; and
a second heater which supplies heat to a second bonding area of the display module,
the interlayer insulating film comprises a package area and a general area arranged with each other in a first direction,
the package element is disposed on the package area of the interlayer insulating film,
in the first bonding area, the package area and the sub-area overlap each other in a thickness direction of the display panel, and
in the second bonding area, the general area and the sub-area overlap each other in the thickness direction of the display panel.

17. The electronic device of claim 16, wherein the apparatus for manufacturing the display device further comprises a thermal bonding device which supplies heat to the first bonding area and the second bonding area.

18. The electronic device of claim 16, wherein the apparatus for manufacturing the display device further comprises a support plate which:
transfers heat supplied to the support plate from the first heater and heat supplied to the support plate from the second heater to the display module, and
supports the display module.

19. The electronic device of claim 16, wherein when the heat from the first heater and the heat from the second heater are supplied to the display module, an amount of the heat supplied from the first heater to the first bonding area is different from an amount of the heat supplied from the second heater to the second bonding area.

20. The electronic device of claim 19, wherein when the heat from the first heater and the heat from the second heater are supplied to the display module, a surface heat loss rate of the package area is greater than a surface heat loss rate of the general area.
